(19) United States
(12) Patent Application Publication
(10) Pub. No.: US 2022/0343810 A1
(43) Pub. Date: Oct. 27, 2022

(54) DISPLAY DEVICE AND TILED DISPLAY

(71) Applicant: Samsung Display Co., LTD., Yongin-si (KR)

(72) Inventors: Hoon KIM, Suwon-si (KR); Won Tae KIM, Suwon-si (KR); Yong Sik HWANG, Seoul (KR)

(21) Appl. No.: 17/539,370

(22) Filed: Dec. 1, 2021

(30) Foreign Application Priority Data
Apr. 22, 2021 (KR) 10-2021-0052172

(51) Int. Cl. G09F 9/302; H01L 27/15; G09F 9/33; H01L 33/38; H01L 33/64

(52) U.S. Cl. CPC G09F 9/3026; H01L 27/156; G09F 9/33; H01L 33/38; H01L 33/642

(57) ABSTRACT

A display device and a tiled display are provided. The display device includes: a substrate having a display area and a non-display area which are defined thereon; a circuit element layer disposed on the substrate and including a conductive layer; an electrode layer disposed on the circuit element layer and including first and second electrodes spaced apart from each other; a light-emitting element disposed between the first electrode and the second electrode; and a dummy pattern disposed in a heat dissipation dummy area located at an edge of the display area. The dummy pattern includes a first layer and a second layer, the first layer is made of or includes a same material as the conductive layer of the circuit element layer, and the second layer is disposed above the first layer and in contact with at least a part of the first layer.

This application claims priority to Korean Patent Application No. 10-2021-0052172, filed on Apr. 22, 2021, and all the benefits accruing therefrom under 35 U.S.C. § 119, the content of which in its entirety is herein incorporated by reference.

### BACKGROUND

### 1. Field of the Disclosure

The disclosure relates to a display device and a tiled display.

### 2. Description of the Related Art

A display device becomes more and more important as multimedia technology evolves. Accordingly, a variety of types of display devices such as organic light-emitting display (“OLED”) devices and liquid-crystal display (“LCD”) devices are currently used.

The display device includes a display panel such as an organic light-emitting display panel and a liquid-crystal display panel for displaying images. Among them, the light-emitting display panel may include light-emitting elements. For example, light-emitting diodes (“LEDs”) may include an organic light-emitting diode (OLED) using an organic material as a luminescent material, and an inorganic light-emitting diode using an inorganic material as a luminescent material.

### SUMMARY

Aspects of the disclosure provide a display device in which a dummy pattern having a stack structure made up of a plurality of conductive layers (or metal layers) is disposed in a heat dissipation dummy area located between a light exit area and a non-display area, to form a heat dissipation path, so that damage by heat generated to an element disposed in the light exit area during a cutting process can be effectively reduced.

It should be noted that aspects of the disclosure are not limited to the above-mentioned aspect; and other aspects of the disclosure will be apparent to those skilled in the art from the following descriptions.

According to an aspect of the disclosure, there is provided a display device including: a substrate having a display area and a non-display area which are defined thereon; a circuit element layer disposed on the substrate and including a conductive layer; an electrode layer disposed on the circuit element layer and including first and second electrodes spaced apart from each other; a light-emitting element disposed between the first electrode and the second electrode; and a dummy pattern disposed in a heat dissipation dummy area located at an edge of the display area. The dummy pattern includes a first layer and a second layer, the first layer is made of or includes the same material as the conductive layer of the circuit element layer, and the second layer is disposed above the first layer and in contact with at least a part of the first layer.

According to an embodiment of the disclosure, a display device includes: a substrate having a display area and a non-display area which are defined thereon; a circuit element layer disposed on the substrate and including a conductive layer, an electrode layer disposed on the circuit element layer and including first and second electrodes spaced apart from each other, a light-emitting element disposed between the first electrode and the second electrode, and a dummy pattern disposed in a heat dissipation dummy area located at an edge of the display area. The dummy pattern includes a first layer and a second layer, the first layer is made of or includes the same material as the conductive layer of the circuit element layer, and the second layer is disposed above the first layer and in contact with at least a part of the first layer.

The second layer may be made of or include the same material as the electrode layer.

The first layer may be disposed on the same layer as the conductive layer, and the second layer is disposed on the same layer as the electrode layer.

At least one of the first layer and the second layer may include a metal material.

The first electrode and the second electrode may be extended in a first direction and are spaced apart from each other in a second direction intersecting the first direction, and the second layer may be spaced apart from the electrode layer in the second direction.

The second layer may have the same shape as the first electrode in a plan view.

The second layer may include a first pattern and a second pattern spaced apart from each other on the first layer, where the first pattern may have the same shape as the first electrode in the plan view, and the second pattern may have the same shape as the second electrode in the plan view.

The first electrode and the second electrode may be extended in a first direction and be spaced apart from each other in a second direction intersecting the first direction, and the second layer may be spaced apart from the electrode layer in the first direction.

The second layer may include a first pattern and a second pattern spaced apart from each other on the first layer, where the first pattern may be disposed on a virtual extension line of the first electrode in the plan view, and the second pattern may be disposed on a virtual extension line of the second electrode in the plan view.

The display device may further include: a first contact electrode in contact with the first electrode and a first end of the light-emitting element; and a second contact electrode in contact with the second electrode and a second end of the light-emitting element, where the second layer may be made of or include the same material as one of the electrode layer, the first contact electrode, and the second contact electrode.

The display device may further include: a first contact electrode in contact with the first electrode and the first end of the light-emitting element; and a second contact electrode in contact with the second electrode and the second end of the light-emitting element. The dummy pattern may further include a third layer disposed on the second layer, the second layer may be made of or include the same material as the electrode layer, and the third layer may be made of or include the same material as one of the first contact electrode and the second contact electrode.

The circuit element layer may further include a via-layer disposed on the conductive layer and the first layer. The electrode layer and the second layer may be disposed on the via-layer, the first electrode may be in contact with the conductive layer through a first contact hole penetrating the via-layer, and the second layer may be in contact with the first layer through a second contact hole penetrating the via-layer.

The display area may include a light exit area and a blocking area surrounding the light exit area, where the light exit area may be located on an inner side of the heat dissipation dummy area in the display area, the dummy pattern may be disposed in the blocking area located between the light exit area and the non-display area, and the light-emitting element may be disposed between the first electrode and the second electrode in the light exit area.

The display device may further include a wavelength control layer disposed over the light-emitting element in the light exit area, and a light-blocking member disposed on the via-layer in the blocking area, where the light-blocking member may cover the dummy pattern.

The display device may further include a bank disposed between the via-layer and the electrode layer in the light exit area, where the dummy pattern may further include a third layer disposed between the via-layer and the second layer in the heat dissipation dummy area, and the third layer may be made of or include the same material as the bank.

The display device may further include a fixed pattern disposed on the light-emitting element to expose opposite ends of the light-emitting element, where the dummy pattern may further include a third layer disposed on the second layer, and the fixed pattern and the third layer may be made of or include the same material.

According to an embodiment of the disclosure, a display device includes: a substrate having a display area and a non-display area which are defined thereon, where the display area includes a light exit area and a heat dissipation dummy area; a semiconductor layer disposed on the substrate and located in the display area; a gate insulator disposed on the semiconductor layer; a first conductive layer disposed on the gate insulator and including a gate electrode located in the display area; an interlayer dielectric film disposed on the first conductive layer; a second conductive layer disposed on the interlayer dielectric film, and including a source electrode and a drain electrode located in the display area, and a first heat dissipation dummy pattern located in the heat dissipation dummy area; a via-layer disposed on the second conductive layer and located in the display area; a third conductive layer disposed on the via-layer, and including first and second electrodes at least partially located in the light exit area, and a second heat dissipation pattern located in the heat dissipation dummy area; and a plurality of light-emitting elements disposed in the light exit area. The heat dissipation dummy area is located between the light exit area and the non-display area, the first electrode and the second electrode are spaced apart from each other, the plurality of light-emitting elements is disposed between the first electrode and the second electrode, the first electrode is electrically connected to the source electrode through a first contact hole penetrating the via-layer, and the second heat dissipation pattern is in direct contact with the first heat dissipation pattern through a second contact hole penetrating the via-layer.

According to an embodiment of the disclosure, a tiled display including a plurality of display devices is provided. Each of the display device includes: a substrate having a display area and a non-display area which are defined thereon; a circuit element layer disposed on the substrate and including a conductive layer; an electrode layer disposed on the circuit element layer and including first and second electrodes spaced apart from each other; a light-emitting element disposed between the first electrode and the second electrode; and a dummy pattern disposed in a heat dissipation dummy area located at an edge of the display area. The dummy pattern includes a first layer made of or including the same material as the conductive layer of the circuit element layer, and a second layer disposed above the first layer and in contact with at least a part of the first layer.

The second layer may be made of or include the same material as the electrode layer.

The first layer may be disposed on the same layer as the conductive layer, and the second layer may be disposed on the same layer as the electrode layer.

According to an embodiment of the disclosure, a display device may include a dummy pattern having a stack structure made up of a plurality of conductive layers (or metal layers) in a heat dissipation dummy area located between a light exit area and a non-display area. The dummy pattern may include at least one metal layer including a metal material, and the plurality of layers forming the dummy pattern may be in contact with each other through at least one contact hole to have a heat dissipation path through which heat is conducted from top to bottom. Accordingly, it is possible to reduce damage to the elements disposed in the light exit area due to heat generated during the cutting process among the process of fabricating the display device.

In addition, as some of the plurality of heat dissipation patterns forming the dummy pattern is formed in the same or similar patterns as the electrode layer and the contact electrodes forming a light-emitting element layer without any additional mask process, it is possible to prevent a decrease in the efficiency of the process of fabricating the display device.

It should be noted that effects of the disclosure are not limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view of a tiled display according to an embodiment of the disclosure.

FIG. 2 is a plan view of a tiled display according to an embodiment of the disclosure.

FIG. 3 is a cross-sectional view of a tiled display according to an embodiment of the disclosure.

FIG. 4 is a plan view showing a plurality of areas of a tiled display according to an embodiment.

FIG. 5 is a plan view showing a plurality of areas of a display device according to an embodiment.

FIG. 6 is an enlarged plan view showing an example of area A of FIG. 4.

FIG. 7 is an enlarged plan view showing an example of a layout of area B of FIG. 6.

FIG. 8 is a plan view showing a wavelength control layer and a first light-blocking member disposed in one pixel shown in FIG. 7.

FIG. 9 is a cross-sectional view showing an example, taken along line I-I′ of the tiled display of FIG. 6.

FIG. 10 is an enlarged plan view showing an example of a layout of area C of FIG. 6.

FIG. 11 is a plan view showing a wavelength control layer and a first light-blocking member disposed in one pixel shown in FIG. 10.

FIG. 12 is a view showing a light-emitting element according to an embodiment of the disclosure.

FIG. 13 is a cross-sectional view showing an example, taken along line II-II′ of the tiled display of FIG. 6.

FIG. 14 is a cross-sectional view showing an example, taken along line III-III′ of the tiled display of FIG. 6.

FIG. 15 is a cross-sectional view showing another example, taken along line II-II′ of the tiled display of FIG. 6.

FIG. 16 is a cross-sectional view showing yet another example, taken along line II-II′ of the tiled display of FIG. 6.

FIG. 17 is a cross-sectional view showing still another example, taken along line II-II′ of the tiled display of FIG. 6.

FIG. 18 is a cross-sectional view showing another example, taken along line I-I′ of the tiled display of FIG. 6.

FIG. 19 is an enlarged plan view showing another example of a layout of area C of FIG. 6.

FIG. 20 is a plan view showing a wavelength control layer and a first light-blocking member disposed in one pixel shown in FIG. 19.

FIGS. 21 to 25 are plan views and cross-sectional views for illustrating a cutting process during a process of fabricating a display device.

FIGS. 26 and 27 are cross-sectional views showing another example of a display mother substrate.

### DETAILED DESCRIPTION

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Hereinafter, embodiments will be described with reference to the accompanying drawings.

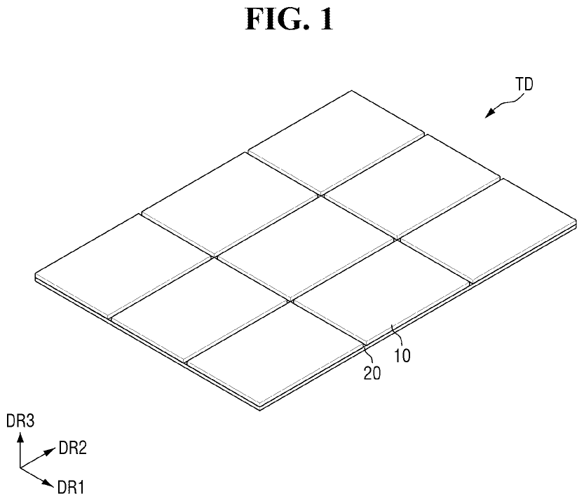

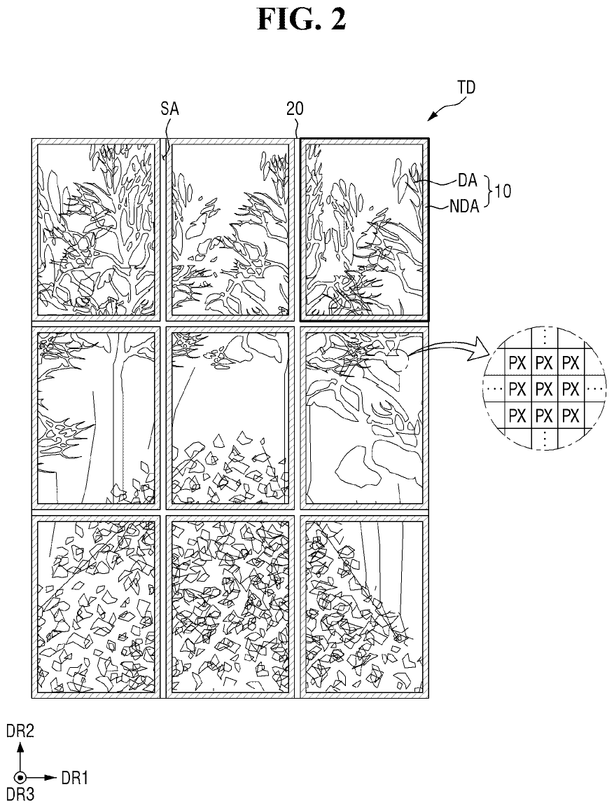

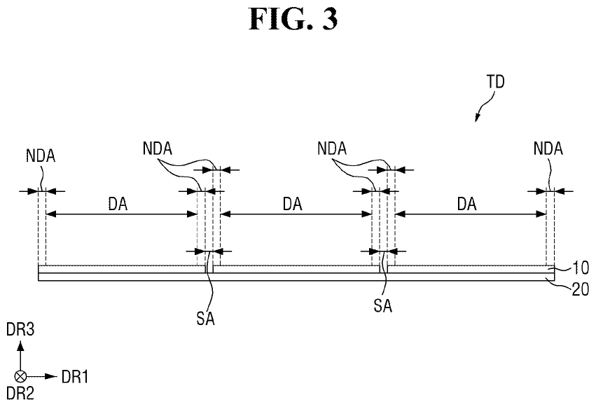

FIG. 1 is a perspective view of a tiled display according to an embodiment of the disclosure. FIG. 2 is a plan view of a tiled display according to an embodiment of the disclosure. FIG. 3 is a cross-sectional view of a tiled display according to an embodiment of the disclosure.

Referring to FIGS. 1 to 3, a tiled display TD displays a moving image or a still image. The tiled display TD may be implemented in any electronic device that provides a display screen. For example, the tiled display TD may include a television set, a laptop computer, a monitor, an electronic billboard, the Internet of Things devices, a mobile phone, a smart phone, a tablet personal computer (“PC”), an electronic watch, a smart watch, a watch phone, a head-mounted display device, a mobile communications terminal, an electronic notebook, an electronic book, a portable multimedia player (“PMP”), a navigation device, a game console and a digital camera, a camcorder, etc.

According to an embodiment of the disclosure, the tiled display TD may include a plurality of display devices 10. The tiled display TD may further include a bottom plate 20.

A first direction DR1, a second direction DR2 and a third direction DR3 are defined in the drawings. The tiled display TD or display devices 10 according to the embodiments of the disclosure will be described with reference to the drawings. The first direction DR1 may be perpendicular to the second direction DR2 in a plane (i.e., in a plan view). The third direction DR3 may be perpendicular to the plane where the first direction DR1 and the second direction DR2 are located. The third direction DR3 may be perpendicular to each of the first direction DR1 and the second direction DR2. In the following description of the tiled display TD or the display devices 10 according to the embodiments of the disclosure, the third direction DR3 refers to the thickness direction (or the display side) of the tiled display TD or the display devices 10.

A display surface may be located on one side of the tiled display TD in the third direction DR3, i.e., the thickness direction. In the following description, the upper side of the tiled display TD or the display devices 10 refers to the side in the third direction DR3 where images are displayed, and the upper surface of the tiled display TD or the display devices 10 refers to the surface facing the side in the third direction DR3 in this application, unless specifically stated otherwise. In addition, the lower side refers to the opposite side in the third direction DR3, and likewise the lower surface refers to the surface facing the opposite side in the third direction DR3. As used herein, the terms “left,” “right,” “upper” and “lower” sides refer to relative positions when the tiled display TD or the display devices 10 are viewed from the top. For example, the right side refers to one side in the first direction DR1, the left side refers to the opposite side in the first direction DR1, the upper side refers to one side in the second direction DR2, and the lower side refers to the opposite side in the second direction DR2.

The tiled display TD may have a rectangular shape including shorter sides extending in the first direction DR1 and longer sides extending in the second direction DR2 when viewed from the top (i.e., in a plan view). The tiled display TD according to the invention may have, but is not limited to, a generally planar shape. The tiled display TD may have a three-dimensional shape, giving a viewer a three-dimensional experience. For example, when the tiled display TD has a three-dimensional shape, at least some of the display devices 10 may have a curved shape, which will be described later. For another example, the display devices 10 may have a flat shape and may be arranged with predetermined angles, so that the tiled display TD may have a three-dimensional shape. The tiled display TD includes a plurality of display devices 10 to achieve a large display area where images are displayed.

The bottom plate 20 may serve to provide and support an area in which the plurality of display devices 10 is disposed. The shape of the bottom plate 20 may follow the shape of the tiled display TD when viewed from the top. According to an embodiment of the disclosure where the tiled display TD has a rectangular shape having shorter sides extending in the first direction DR1 and longer sides extending in the second direction DR2 when viewed from the top, the bottom plate 20 may have a rectangular shape having shorter sides extending in the first direction DR1 and longer sides extending in the second direction DR2. Although not shown in the drawings, various kinds of lines and cables for electrically connecting the plurality of display devices 10 may be disposed on the bottom plate 20, and fastening members for fixing the plurality of the display devices 10 may be further disposed.

The plurality of display devices 10 may be disposed on the bottom plate 20. The plurality of display devices 10 according to the invention may be fixed to, but is not limited to, one surface (e.g., upper surface) of the bottom plate 20 through fastening members.

The plurality of display devices 10 may be arranged in a matrix on the bottom plate 20. The plurality of display devices 10 may be spaced apart from one another in the first direction DR1 and the second direction DR2 when viewed from the top (i.e., in a plan view), and may be arranged with a predetermined space therebetween. The display devices 10 disposed adjacent to each other may be spaced apart so that their longer sides and/or the shorter sides face each other. As the display devices 10 are spaced apart from each other by a predetermined space on the bottom plate 20, it is possible to prevent one of the display devices 10 from being damaged by another adjacent one even if the display devices 10 are expanded by heat generated therein. Although the display devices 10 are arranged in a 3×3 matrix in the example shown in the drawings, the number and arrangement of the display devices 10 according to the invention are not limited thereto.

Although the directions in which the display devices 10 are arranged to coincide with the first and second directions DR1 and DR2 in which the longer and shorter sides of the tiled display are extended in the drawings, respectively, the disclosure is not limited thereto. For example, the directions in which the display devices 10 are arranged may be inclined by predetermined angles with respect to the directions in which the longer side/shorter side of the tiled display TD are extended.

Each of the display devices 10 may have a rectangular shape including shorter sides extending in the first direction DR1 and longer sides extending in the second direction DR2 when viewed from the top. It should be understood that the disclosure is not limited thereto. Each of the display devices 10 may have a rectangular shape including longer sides extending in the first direction DR1 and shorter sides extending in the second direction DR2. The plurality of display devices 10 may have the same shape when viewed from the top. In addition, the plurality of display devices 10 may have the same size. It should be understood that the disclosure is not limited thereto. The plurality of display devices 10 may have different shapes or different sizes when viewed from the top.

Each of the plurality of display devices 10 includes a display panel providing a display screen. Examples of the display panel may include an inorganic light-emitting diode display panel, an organic light-emitting display panel, a quantum-dot light-emitting display panel, a plasma display panel, a field emission display panel, etc. In the following description, an inorganic light-emitting diode display panel is employed as an example of the display panel, but the disclosure is not limited thereto. Any other display panel may be employed as long as the technical idea of the disclosure can be equally applied.

Each of the display devices 10 may include a display area DA and anon-display area NDA. In the display area DA, images can be displayed. In the non-display area NDA, images are not displayed.

The shape of the display area DA may follow the shape of the display device 10. For example, the shape of the display area DA may have a rectangular shape generally similar to the shape of the display device 10 when viewed from the top (i.e., in a plan view). The display area DA may generally occupy the center of the display device 10.

The display area DA may include a plurality of pixels PX. Each of the pixels PX refers to a repeating minimum unit for displaying images. In order to display full color, each of the pixels PX may include a plurality of sub-pixels that emits different colors. The plurality of pixels PX may be arranged in a matrix. The shape of each of the pixels PX may be rectangular or square when viewed from the top. In an embodiment, each of the pixels PX may include a plurality of light-emitting elements made of or including inorganic particles. It should be understood that the disclosure is not limited thereto.

The non-display area NDA may be disposed around the display area DA. The non-display area NDA may surround the display area DA entirely or partially.

The tiled display TD may further include a boundary area SA (or a separation area) between adjacent display devices 10. As described above, the display devices 10 may be spaced apart from one another by a predetermined distance, and the boundary area SA may be the space between the display devices 10 disposed adjacent to each other. The boundary area SA may also be referred to as a seam. The boundary area SA may be an area between the non-display areas NDA of the display device 10 disposed adjacent to each other. The boundary area SA may be surrounded by the non-display areas NDA of the display devices 10 disposed adjacent to each other.

No image is displayed in the boundary area SA of the tiled display TD and the non-display area NDA of each of the plurality of display devices 10. Therefore, if the width of the boundary area SA or the width of the non-display area NDA on which no image is displayed is large, a user may notice the boundary area SA or the non-display area NDA, and thus the user cannot get immerged into contents displayed on the tiled display TD. For this reason, in order for the display devices 10 to display images as if they are a single display, the display devices 10 may be so close to each other that the boundary areas SA where no image is displayed are not recognized by a user. In addition, the width of the non-display areas NDA of the display devices 10 where no image is displayed may be reduce so that they are not recognized by the user. That is to say, the tiled display TD can allow a viewer to get immersed into the images by eliminating seams between the display devices 10 by way of preventing the non-display areas NDA or the boundaries between the plurality of display devices 10 from being perceived.

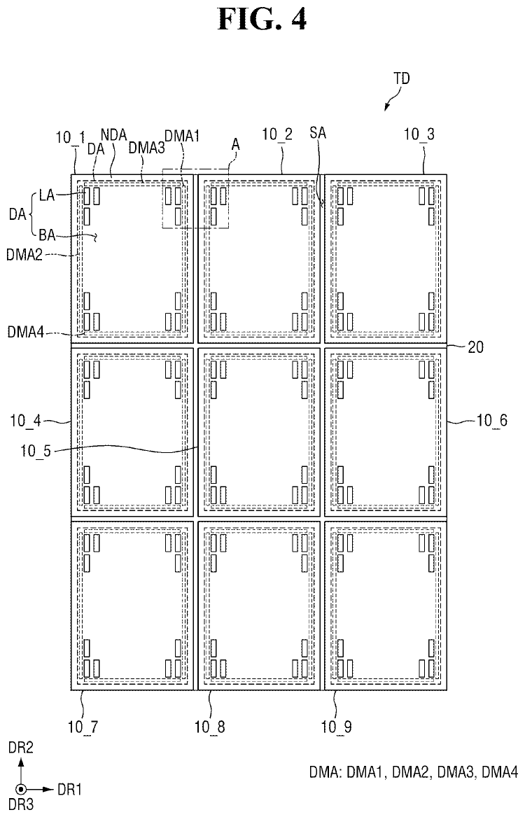

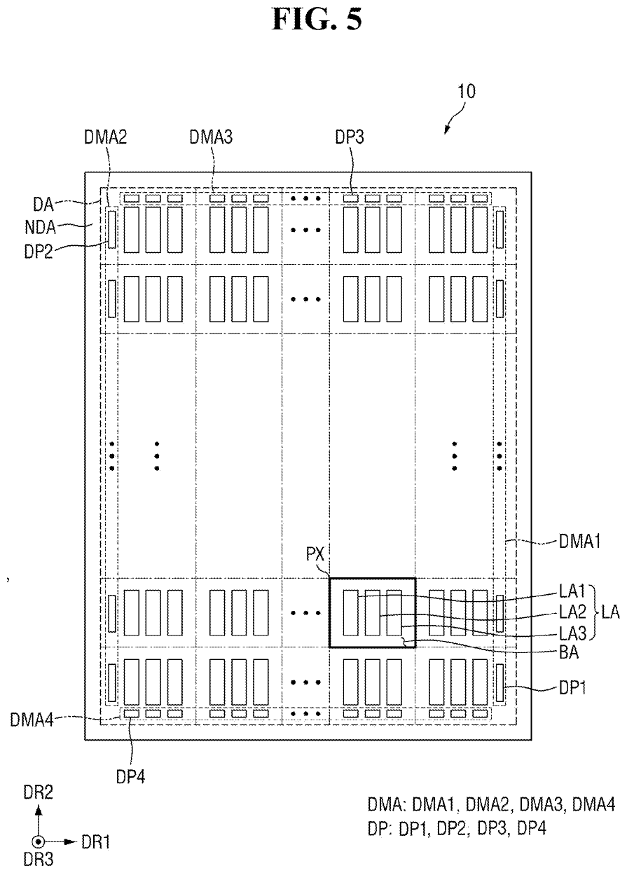

FIG. 4 is a plan view showing a plurality of areas of a tiled display according to an embodiment. FIG. 5 is a plan view showing a plurality of areas of a display device according to an embodiment.

Referring to FIG. 4, the tiled display TD may include a plurality of display devices 10: 10_1, 10_2, 10_3, 10_4, 10_5, 10_6, 10_7, 10_8 and 10_9, which are spaced apart from one another with a predetermined space. For example, the plurality of display devices 10 may include first to ninth display devices 10_1, 10_2, 10_3, 10_4, 10_5, 10_6, 10_7, 10_8 and 10_9. In the following description, a specific one of the first to ninth display devices 10_1, 10_2, 10_3, 10_4, 10_5, 10_6, 10_7, 10_8 and 10_9 will be referred to as a “first display device 10_1,” “second display device 10_2,” and so on. On the other hand, a random one of the first to ninth display devices 10_1, 10_2, 10_3, 10_4, 10_5, 10_6, 10_7, 10_8 and 10_9 will be referred to as a “display device 10”. All of the first to ninth display devices 10_1, 10_2, 10_3, 10_4, 10_5, 10_6, 10_7, 10_8, 10_9 will be collectively referred to as a “plurality of display devices 10” or “display devices 10.”

The first to ninth display devices 10: 10_1, 10_2, 10_3, 10_4, 10_5, 10_6, 10_7, 10_8 and 10_9 may be spaced apart from each other in the first direction DR1 and/or the second direction DR2. Although nine display devices 10 are arranged in a 3×3 matrix in the example shown in the drawings, the number and arrangement of the display devices 10 according to the invention are not limited to those shown in FIG. 4. The number of the display devices 10 may be determined depending on the sizes of the display devices 10 and the tiled display TD.

Some display devices 10_2, 10_4, 10_6 and 10_8 among the plurality of display devices 10 included in the tiled display TD may be disposed at the edges (i.e., side) of the tiled display TD. Some other display devices 10_1, 10_3, 10_7 and 10_9 among the plurality of display devices 10 included in the tiled display TD may be disposed adjacent to the corners of the tiled display TD. Another display device 10_5 among the plurality of display devices 10 included in the tiled display TD may be disposed on the inner side of the tiled display TD, and may be surrounded by the other display devices 10_1, 10_2, 10_3, 10_4, 10_6, 10_7, 10_8 and 10_9.

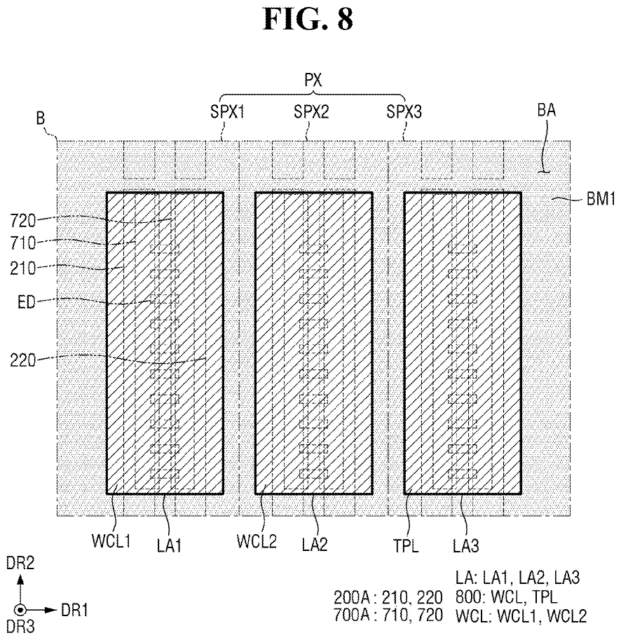

Referring to FIGS. 4 and 5, the display area DA of the display device 10 may include light exit areas LA and a blocking area BA surrounding the light exit areas LA. The light exit areas LA may be disposed in a plurality of sub-pixels included in a pixel PX, respectively. The light exit areas LA and the blocking area BA may be defined by a first light-blocking member BM1 (See FIG. 8) to be described later.

In the light exit areas LA, light emitted from the light-emitting element layer of the display device 10 is provided to the outside. In the blocking area BA, light emitted from the light-emitting element layer does not transmit to the outside.

The light exit areas LA may include a first light exit area LA1, a second light exit area LA2, and a third light exit area LA3. In the first to third light exit areas LA1, LA2 and LA3, light having predetermined peak wavelengths may be output to the outside of the display device 10. The first light exit area LA1 may output light of a first color, the second light exit area LA2 may output light of a second color, and the third light exit area LA3 may output light of a third color. For example, the light of the first color may be red light having a peak wavelength in the range of 610 to 650 nanometers (nm), the light of the second color may be green light having a peak wavelength in the range of 510 to 550 nm, and the light of the third color may be blue light having a peak wavelength in the range of 440 to 480 nm. It is, however, to be understood that the disclosure is not limited thereto.

The first to third light exit areas LA1, LA2 and LA3 may be sequentially and repeatedly arranged along the first direction DR1 in the display area DA of the display devices 10. The shape of the first to third light exit areas LA1, LA2 and LA3 according to the invention may be, but is not limited to, a rectangle having the width in the second direction DR2 larger than the width in the first direction DR1.

The blocking area BA may be disposed to surround the light exit areas LA. Specifically, the blocking area BA may be disposed to surround the first to third light exit areas LA1, LA2 and LA3. The blocking area BA of the adjacent pixels PX may be connected to each other as one, and further, the blocking area BA of all pixels PX may be connected to one another as one. It is, however, to be understood that the disclosure is not limited thereto. Adjacent light exit areas LA may be distinguished by the blocking area BA. The blocking area BA can prevent a mixture of lights of different colors output from the first to third light exit areas LA1, LA2 and LA3.

The non-display area NDA of the display device 10 may surround the display area DA. The non-display area NDA may be disposed adjacent to the sides of the display device 10 when viewed from the top (i.e., in a plan view). For example, the display area DA may have a rectangular shape when viewed from the top, and the non-display areas NDA may be disposed to be adjacent to the four sides of the display area DA. Specifically, the non-display area NDA may include a first non-display area disposed adjacent to a first longer side (right side of FIG. 5) of the display device 10, a second non-display area disposed adjacent to a second longer side (left side of FIG. 5) of the display device 10, a third non-display area disposed adjacent to the first shorter side (upper side of FIG. 5) of the display device 10, and a fourth non-display area disposed adjacent to the second shorter side (lower side of FIG. 5) of the display device 10.

According to an embodiment of the disclosure, the display device 10 may further include heat dissipation dummy areas DMA located at the edges of the display area DA. In the heat dissipation dummy areas DMA, the dummy patterns DP may be disposed, which prevent the elements of the display device 10 from being damaged or deformed by heat generated a during the process of cutting a display mother substrate using the laser in the process of fabricating the display device 10 to be described later (hereinafter referred to as a cutting process).

The heat dissipation dummy areas DMA may be disposed at the edges of the display area DA. The heat dissipation dummy areas DMA may be disposed between the light exit areas LA disposed at the outermost positions and the non-display areas NDA. The heat dissipation dummy areas DMA may overlap with part of the blocking area BA disposed between the light exit areas LA disposed at the outermost positions and the non-display areas NDA in a plan view.

In an embodiment where the display area DA has a rectangular shape when viewed from the top, the heat dissipation dummy areas DMA may include a first heat dissipation dummy area DMA1, a second heat dissipation dummy area DMA2, a third heat dissipation dummy area DMA3, and a fourth heat dissipation dummy area DMA4.

The first heat dissipation dummy area DMA1 may be disposed between the light exit area LA disposed at the rightmost position of the display area DA (or the third light exit area LA3) and the non-display area NDA adjacent thereto. The second heat dissipation dummy area DMA2 may be disposed between the light exit area LA disposed at the leftmost position of the display area DA (or the first light exit area LA1) and the non-display area NDA adjacent thereto. The first heat dissipation dummy area DMA1 and the second heat dissipation dummy area DMA2 may be extended along the second direction DR2 when viewed from the top (i.e., in a plan view).

The third heat dissipation dummy area DMA3 may be disposed between the light exit areas LA disposed at the uppermost positions of the display area DA (or the first to third light exit areas LA1, LA2 and LA3) and the non-display area NDA adjacent thereto. The fourth heat dissipation dummy area DMA4 may be disposed between the light exit areas LA disposed at the lowermost positions of the display area DA (or the first to third light exit areas LA1, LA2 and LA3) and the non-display area NDA adjacent thereto. The third heat dissipation dummy area DMA3 and the fourth heat dissipation dummy area DMA4 may be extended along the first direction DR1 when viewed from the top (i.e., in a plan view).

According to an embodiment of the disclosure, the display device 10 may include dummy patterns DP. The dummy patterns DP may be disposed in the heat dissipation dummy areas DMA. The dummy patterns DP may have a stack structure of metal layers (or conductive layers). As the dummy patterns DP are disposed between the light exit areas LA disposed at the outermost positions and the non-display area NDA and have the structure in which a plurality of layers including a metal material are stacked on one another, the display device 10 can have heat dissipation paths through which heat generated by a laser during the cutting process can be diffused to the dummy patterns DP made up of the plurality of layers. Such heat dissipation paths of the heat diffused by the dummy patterns DP will be described later after the cross-sectional structure of the display device 10 is described.

The dummy patterns DP may include a plurality of dummy patterns DP1, DP2, DP3 and DP4. For example, the dummy patterns DP may include a first dummy pattern DP1, a second dummy pattern DP2, a third dummy pattern DP3 and a fourth dummy pattern DP4.

The first dummy pattern DP1 may be disposed in the first heat dissipation dummy area DMA′. The first dummy pattern DP1 disposed in the first heat dissipation dummy area DMA1 may include a plurality of parts. The parts of the first dummy pattern DP1 may be arranged in the second direction DR2 in the first heat dissipation dummy area DMA′. The parts of the first dummy pattern DP1 may be spaced apart from one another in the second direction DR2, but the disclosure is not limited thereto. The parts of the first dummy pattern DP1 may be disposed adjacent to the right side of the plurality of light exit areas LA disposed on the rightmost positions.

The second dummy pattern DP2 may be disposed in the second heat dissipation dummy area DMA2. The second dummy pattern DP2 disposed in the second heat dissipation dummy area DMA2 may include a plurality of parts. The parts of the second dummy pattern DP2 may be arranged in the second direction DR2 in the second heat dissipation dummy area DMA2. The parts of the second dummy pattern DP2 may be spaced apart from one another in the second direction DR2, but the disclosure is not limited thereto. The parts of the second dummy pattern DP2 may be disposed adjacent to the left side of the plurality of light exit areas LA disposed on the leftmost positions.

The third dummy pattern DP3 may be disposed in the third heat dissipation dummy area DMA3. The third dummy pattern DP3 disposed in the third heat dissipation dummy area DMA3 may include a plurality of parts. The parts of the third dummy pattern DP3 may be arranged in the first direction DR1 in the third heat dissipation dummy area DMA3. The parts of the third dummy pattern DP3 may be spaced apart from one another in the first direction DR1, but the disclosure is not limited thereto. The parts of the third dummy pattern DP3 may be disposed adjacent to the upper side of the plurality of light exit areas LA disposed on the uppermost positions.

The fourth dummy pattern DP4 may be disposed in the fourth heat dissipation dummy area DMA4. The fourth dummy pattern DP4 disposed in the fourth heat dissipation dummy area DMA4 may include a plurality of parts. The parts of the fourth dummy pattern DP4 may be arranged in the first direction DR1 in the fourth heat dissipation dummy area DMA4. The parts of the fourth dummy pattern DP4 may be spaced apart from one another in the first direction DR1, but the disclosure is not limited thereto. The parts of the fourth dummy pattern DP4 may be disposed adjacent to the lower side of the plurality of light exit areas LA disposed on the lowermost positions.

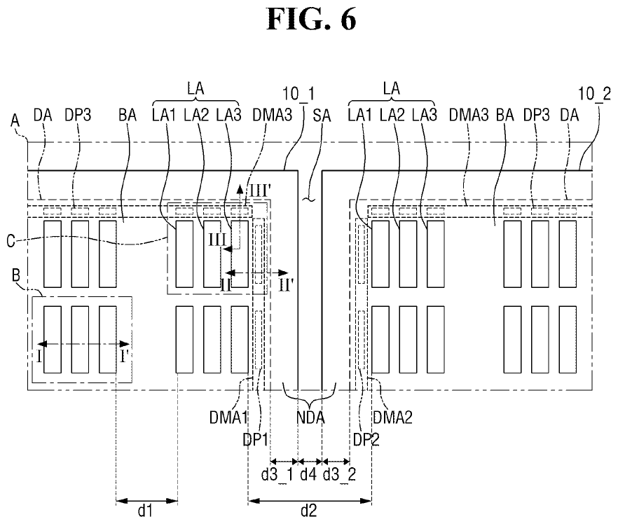

FIG. 6 is an enlarged plan view showing an example of area A of FIG. 4.

Referring to FIGS. 4 to 6, in the first display device 10_1, a first distance d1 between the first light exit area LA1 of a pixel PX and the third light exit area LA3 of another pixel PX adjacent to the left of the pixel PX in the same row may be constant. Likewise, in the second display device 10_2, a first distance d1 between the first light exit area LA1 of a pixel PX and the third light exit area LA3 of another pixel PX adjacent to the left of the pixel PX in the same row may be constant. A second distance d2 between the third light exit area LA3 of the pixel PX disposed on the right outermost position of the first display device 10_1 and the first light exit area LA1 of the pixel PX of the second display device 10_2 which is disposed at the left outermost position and faces the third light exit area LA3 in the first direction DR1 may be different from the first distance d1.

The display devices 10 included in the tiled display TD may be spaced apart from one another with the separation area SA therebetween. For example, the first display device 10_1 and the second display device 10_2 may be spaced apart from each other by a predetermined distance d4 with the separation area SA therebetween. The non-display areas NDA may be located between the first display device 10_1 and the second display device 10_2 which are adjacent to each other and spaced apart from each other. As such, the first distance d1 and the second distance d2 may be different from each other due to the distance d4 of the separation area SA between the first display device 10_1 and the second display device 10_2, the width d3_1 of the non-display area NDA of the first display device 10_1 and the width d3_2 of the non-display area NDA of the second display device 10_2.

If there is a larger difference between the first distance d1 and the second distance d2, the boundary area SA or the non-display area NDA may be noticed by a user. As a result, the user cannot get immerged into contents displayed on the tiled display TD. Accordingly, by adjusting the widths d3_1 and d3_2 of the non-display areas NDA of the display devices 10 so that the widths are reduced, it is possible to prevent the user from noticing the boundary area SA of the tiled display TD.

As will be described later, in order to reduce the width of the non-display area NDA of each of the display devices 10, a laser beam may be irradiated to an area adjacent to the display area DA of the display device 10 during a process of cutting the display mother substrate using a laser source. In doing so, heat generated by the laser beam may be easily transferred (or diffused) to the light exit areas LA. In this regard, the display device 10 according to this embodiment includes the dummy patterns DP disposed between the light exit areas LA and the non-display area NDA. Accordingly, the heat that is generated by the laser beam and transferred toward the light exit areas LA may be guided to heat dissipation paths directed to the dummy patterns DP. Accordingly, at least a part of the heat that is generated by the laser beam and transferred to the light exit areas LA can be transferred along the dummy patterns DP through the heat dissipation paths, and thus it is possible to block the heat from being transmitted to the light exit areas LA.

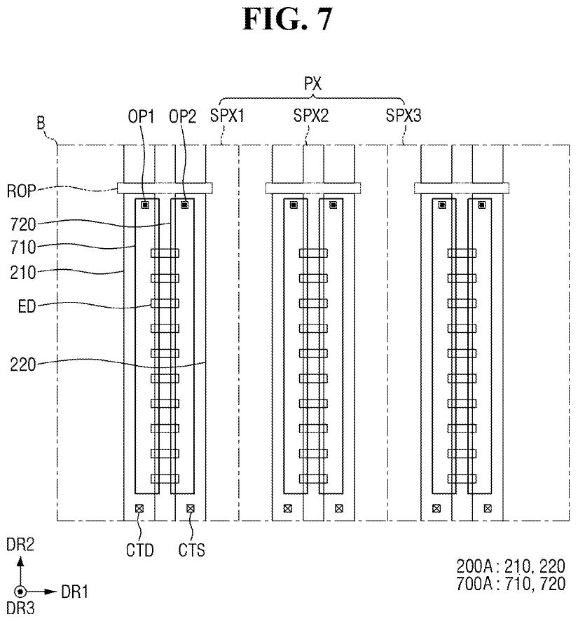

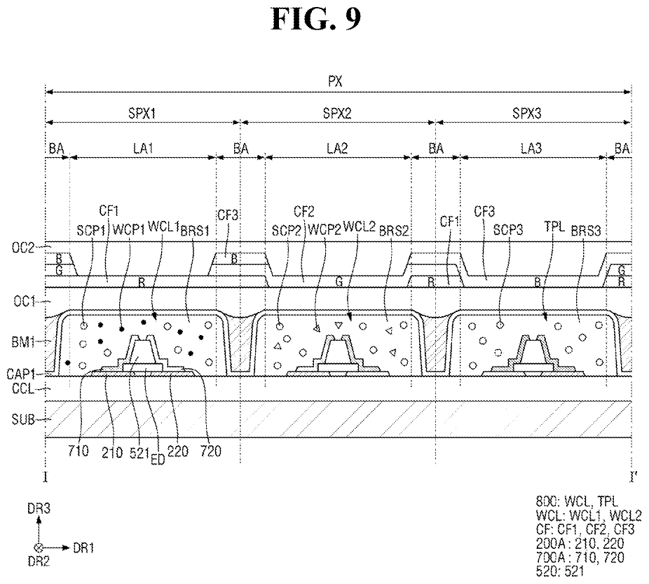

FIG. 7 is an enlarged plan view showing an example of a layout of area B of FIG. 6. FIG. 8 is a plan view showing a wavelength control layer and a first light-blocking member disposed in one pixel shown in FIG. 7. FIG. 9 is a cross-sectional view showing an example, taken along line I-I′ of the tiled display of FIG. 6.

FIGS. 7 to 9 show a planar structure and a cross-sectional structure of one pixel PX disposed inside the display area DA of the display device 10. Hereinafter, the planar structure and the cross-sectional structure of one pixel PX disposed inside the display area DA of the display device 10 will be described with reference to FIGS. 7 to 9.

Referring to FIGS. 7 to 9, one pixel PX may include a plurality of sub-pixels SPXn, where n is a natural number equal to or less than three. For example, the pixel PX may include a first sub-pixel SPX1, a second sub-pixel SPX2 and a third sub-pixel SPX3. Each of the sub-pixels SPXn of the display device 10 may include a light exit area LA and a blocking area BA.

The first to third light exit areas LA1, LA2 and LA3 may be the light exit areas LA of the first to third sub-pixels SPX1, SPX2 and SPX3, respectively. For example, the first light exit area LA1 may be the light exit area LA of the first sub-pixel SPX1, the second light exit area LA2 may be the light exit area LA of the second sub-pixel SPX2, and the third light exit area TA3 may be the light exit area LA of the third sub-pixel SPX3.

The blocking area BA may be disposed to surround the first to third light exit areas LA1, LA2 and LA3. The blocking area BA of a sub-pixel SPX meets the blocking area BA of an adjacent sub-pixel SPX, regardless of whether the adjacent sub-pixel SPX is in the same pixel PX or not. The blocking area BA of the adjacent sub-pixels SPXn may be connected to each other as one, and further, the blocking area BA of all sub-pixels SPXn may be connected to one another as one. It is, however, to be understood that the disclosure is not limited thereto. The light exit areas LA of the sub-pixels SPXn may be distinguished by the blocking area BA.

The display device 10 may include a substrate SUB, a circuit element layer CCL, a light-emitting element layer, a wavelength control layer 800, a first light-blocking member BM1, and a color filter layer CF. The display device 10 may further include a first capping layer CAP1, a first planarization layer OC1, and a protection layer OC2.

The substrate SUB may be a base substrate or a base member and may be made of or include an insulating material such as a polymer resin. The substrate SUB may be made of or include an insulating material such as glass, quartz and a polymer resin. The substrate SUB may be either a rigid substrate or a flexible substrate that can be bent, folded, or rolled. According to an embodiment of the disclosure, the substrate SUB according to the invention may include, but is not limited to, a glass substrate.

The circuit element layer CCL may be disposed on the substrate SUB. The circuit element layer CCL may be disposed on one surface (e.g., upper surface) of the substrate SUB to drive the pixel PX (or a plurality of sub-pixel SPXn). The circuit element layer CCL may include at least one transistor or the like to drive a light-emitting element layer.

The light-emitting element layer may be disposed on a surface of the circuit element layer CCL. The light-emitting element layer may include an electrode layer 200A, a light-emitting diode ED, contact electrodes 700A, and a first insulating layer 520.

The electrode layer 200A may be disposed on the circuit element layer CCL. The electrode layer 200A may be disposed in the display area DA. The electrode layer 200A may include a first electrode 210 and a second electrode 220 spaced apart from each other.

Each of the first electrode 210 and the second electrode 220 may have a shape extended in the second direction DR2 when viewed from the top (i.e., in a plan view). The first electrode 210 and the second electrode 220 may be spaced apart from each other in the first direction DR1. The first electrode 210 and the second electrode 220 may be arranged such that at least a partial area of the first electrode 210 and the second electrode 220 is located in the light exit area LA of each sub-pixel SPXn. there is.

The first electrode 210 may be electrically connected to the circuit element layer CCL through a first electrode contact hole CTD, and the second electrode 220 may be electrically connected to the circuit element layer CCL through a second electrode contact hole CTS.

Each of the first and second electrodes 210 and 220 may be electrically connected to the light-emitting diodes ED, and a predetermined voltage may be applied so that the light-emitting diodes ED emit light. For example, the first and second electrodes 210 and 220 may be electrically connected to the light-emitting diodes ED disposed between the first electrode 210 and the second electrode 220 through contact electrodes 700A, and may transmit electric signals applied to the first and second electrodes 210 and 220 to the light-emitting diodes ED through the contact electrodes 700A.

The first electrode 210 and the second electrode 220 may be separated from a first electrode 210 and a second electrode 220 of another sub-pixel SPXn adjacent to the sub-pixel SPXn in the second direction DR2, respectively, at a separation region ROP of the sub-pixel SPXn. The first electrode 210 and the second electrode 220 having such a shape may be formed via a process of disconnecting the electrodes at the separation region ROP after the process of disposing the light-emitting diodes ED during the process of fabricating the display device 10 It is, however, to be understood that the disclosure is not limited thereto. In an embodiment, the first and second electrodes 210 and 220 may be extended to another sub-pixel SPXn adjacent to the sub-pixel SPXn in the second direction DR2 to be integrated with the first and second electrodes of the adjacent pixel PX. Alternatively, only one of the first electrode 210 and the second electrode 220 may be separated. The shape and arrangement of the first electrode 210 and the second electrode 220 disposed for each sub-pixel SPXn are not particularly limited herein as long as the first electrode 210 and the second electrode 220 are at least partially spaced apart from each other so that the light-emitting diodes ED can be disposed therebetween.

The first and second electrodes 210 and 220 may be utilized to form an electric field in the sub-pixel SPXn to align the light-emitting diodes ED. The light-emitting diodes ED may be disposed between the first electrode 210 and the second electrode 220 by an electric field formed over the first electrode 210 and the second electrode 220.

The plurality of light-emitting diodes ED may be disposed in the light exit areas LA. The plurality of light-emitting diodes ED may not be disposed in the blocking area BA.

The plurality of light-emitting diodes ED may be disposed on the electrode layer 200A in the light exit area LA. The plurality of light-emitting diodes ED may be disposed between the first electrode 210 and the second electrode 220 in the light exit areas LA.

Each of the light-emitting diodes 30 may have a shape extended in one direction. The direction in which the first and second electrodes 210 and 220 are extended may be substantially perpendicular to the direction in which the light-emitting diodes 30 are extended. The light-emitting diodes ED may be aligned between the first electrode 210 and the second electrode and 220 so that first ends are placed on the first electrode 210 and second ends are placed on the second electrode 220.

The first insulating layer 520 may be disposed on the light-emitting diodes ED. The first insulating layer 520 may include a fixed pattern 521 disposed in the light exit area LA.

The fixed pattern 521 may be partially disposed on the light-emitting diodes ED disposed between the first electrode 210 and the second electrode 220. The fixed pattern 521 may be disposed on the light-emitting diodes ED to expose both ends of the light-emitting diodes ED.

The contact electrodes 700A may be disposed on the fixed pattern 521. The contact electrodes 700A may be disposed in the light exit areas LA. The contact electrodes 700A may include a first contact electrode 710 and a second contact electrode 720 spaced apart from each other.

Each of the first contact electrode 710 and the second contact electrode 720 may have a shape extended in the second direction DR2 when viewed from the top (i.e., in a plan view). The first contact electrode 710 and the second contact electrode 720 may be spaced apart from each other and face each other in the first direction DR1.

The first contact electrode 710 may be disposed on the first electrode 210. The first contact electrode 710 may be in contact with the first ends of the light-emitting diodes ED exposed by the fixed pattern 521. The first contact electrode 710 may be in contact with a part of the first electrode 210 through a first contact opening OP1. The first ends of the light-emitting diodes ED may be electrically connected to the first electrode 210 through the first contact electrode 710.

The second contact electrode 720 may be disposed on the second electrode 220. The second contact electrode 720 may be in contact with the second ends of the light-emitting diodes ED exposed by the fixed pattern 521. The second contact electrode 720 may be in contact with a part of the second electrode 220 through a second contact opening OP2. The second ends of the light-emitting diodes ED may be electrically connected to the second electrode 220 through the second contact electrode 720.

The wavelength control layer 800 may be disposed on the light-emitting diodes ED. The wavelength control layer 800 may be disposed in the light exit areas LA. The wavelength control layer 800 may be disposed in the light exit areas LA1, LA2 and LA3 of each sub-pixel SPXn, but may not be disposed in the blocking area BA.

The wavelength control layer 800 may include a wavelength conversion layer WCL that convert the wavelength of light emitted from the light-emitting diodes ED, and a transparent pattern TPL that transmits light emitted from the light-emitting diodes ED without changing the wavelength of the light.

The wavelength conversion layer WCL or the transparent pattern TPL may be disposed separately in each of the sub-pixels SPXn. The wavelength conversion layer WCL or the transparent pattern TPL may be disposed in the light exit area LA of the display area DA, and the wavelength conversion layer WCL and/or the transparent pattern TPL adjacent to each other may be spaced apart from each other with the first light-blocking member BM1 disposed in the blocking area BA therebetween.

The wavelength conversion layer WCL and the transparent pattern TPL may be disposed on the light-emitting diodes ED. According to an embodiment of the disclosure, the wavelength conversion layer WCL and the transparent pattern TPL may be formed by applying a photosensitive material, exposing it to light, and developing and patterning it. It is, however, to be understood that the disclosure is not limited thereto. The wavelength conversion layer WCL and the transparent pattern TPL may be formed by inkjet printing in another embodiment. In the following description, it is assumed that the wavelength conversion layer WCL and the transparent pattern TPL are formed using a photosensitive material.

The wavelength conversion layer WCL may be disposed in a sub-pixel SPXn with a color different from the wavelength of light emitted from the light-emitting diodes ED so as to convert the wavelength. The transparent pattern TPL may be disposed in a sub-pixel SPXn with the same color as the wavelength of the light emitted from the light-emitting diodes ED. According to the embodiment, the light of the third color is emitted from the light-emitting diodes ED disposed in each sub-pixel SPXn, and the wavelength conversion layer WCL is disposed in each of the first sub-pixel SPX1 and the second sub-pixel SPX2 while the transparent pattern TPL is disposed in the third sub-pixel SPX3.

According to an embodiment of the disclosure, the wavelength conversion layer WCL may include a first wavelength conversion pattern WCL1 disposed in the first sub-pixel SPX1, and a second wavelength conversion pattern WCL2 disposed in the second sub-pixel SPX2.

The first wavelength conversion pattern WCL1 may be disposed in the first light exit area LA1 defined by the first light-blocking member BM1 in the first sub-pixel SPX1. The first wavelength conversion pattern WCL1 may be disposed in the first light exit area LA1 of the first sub-pixel SPX1, to cover a partial area of the electrode layer 200A disposed in the first light exit area LA1, the light-emitting diodes ED, and the contact electrodes 700A.

The first wavelength conversion pattern WCL1 may convert light that has the wavelength of the third color and is emitted from the light-emitting diodes ED into light having the wavelength of the first color different from the third color and then output it. For example, the first wavelength conversion pattern WCL1 may convert blue light emitted from the light-emitting diodes ED into red light and then output it.

The first wavelength conversion pattern WCL1 may include a first base resin BRS1, and first wavelength-converting particles WCP1 dispersed in the first base resin BRS1. The first wavelength conversion pattern WCL1 may further include first scattering particles SCP1 dispersed in the first base resin BRS1.

The second wavelength conversion pattern WCL2 may be disposed in the second light exit area LA2 defined by the first light-blocking member BM1 in the second sub-pixel SPX2. The second wavelength conversion pattern WCL2 may be disposed in the second light exit area LA2 of the second sub-pixel SPX2, to cover a partial area of the electrode layer 200A disposed in the second light exit area LA2, the light-emitting diodes ED, and the contact electrodes 700A.

The second wavelength conversion pattern WCL2 may convert light that has the wavelength of the third color and is emitted from the light-emitting diodes ED into light having the wavelength of the first color different from the third color and then output it. For example, the second wavelength conversion pattern WCL2 may convert blue light emitted from the light-emitting diodes ED into green light and then output it.

The second wavelength conversion pattern WCL2 may include a second base resin BRS2 and second wavelength-converting particles WCP2 dispersed in the second base resin BRS2. The second wavelength conversion pattern WCL2 may further include second scattering particles SCP2 dispersed in the second base resin BRS2.

The transparent pattern TPL may be disposed in the third light exit area LA3 defined by the first light-blocking member BM1 in the third sub-pixel SPX3. The transparent pattern TPL may be disposed in the third light exit area LA3 of the third sub-pixel SPX3, to cover a partial area of the electrode layer 200A disposed in the third light exit area LA3, the light-emitting diodes ED, and the contact electrodes 700A.

The transparent pattern TPL may output the light emitted from the light-emitting diodes ED without changing its wavelength. For example, the transparent pattern TPL transmits blue light emitted from the light-emitting diodes ED while maintaining its wavelength.

The transparent pattern TPL may include a third base resin BRS3. The transparent pattern TPL may further include third scattering particles SCP3 dispersed in the third base resin BRS3.

The first to third base resins BRS1, BRS2 and BRS3 may include a transparent organic material. For example, the first to third base resins BRS1, BRS2 and BRS3 may include an epoxy resin, an acrylic resin, a cardo resin, an imide resin, or the like. The first to third base resins BRS1, BRS2 and BRS3 according to the invention may be made of or include, but is not limited to, the same material.

The first to third scattering particles SCP1, SCP2 and SCP3 may have refractive indexes different from those of the first to third base resins BRS1, BRS2 and BRS3. The first to third scattering particles SCP1, SCP2 and SCP3 may include metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), etc. Examples of the material of the organic particles may include an acrylic resin, a urethane resin, etc. The first to third scattering particles SCP1, SCP2 and SCP3 according to the invention may be made of or include, but is not limited to, the same material.

The first wavelength-converting particles WCP1 may convert the third color into the first color, and the second wavelength-converting particles WCP2 may convert the third color into the second color. For example, the first wavelength-converting material WCP1 may be a material that converts blue light into red light, and the second wavelength-converting material WCP2 may be a material that converts blue light into green light. The first wavelength-converting particles WCP1 and the second wavelength-converting particles WCP2 may be quantum dots, quantum rods, phosphors, etc. The quantum dots may include IV nanocrystals, II-VI compound nanocrystals, III-V compound nanocrystals, IV-VI nanocrystals, or combinations thereof.

The first capping layer CAP1 may be disposed on the wavelength control layer 800 to cover them. The first capping layer CAP1 may encapsulate the outer surface of the wavelength control layer 800. For example, the first capping layer CAP1 may encapsulate the first wavelength conversion pattern WCL1, the second wavelength conversion pattern WCL2 and the transparent pattern TPL, to prevent damage or contamination to the first wavelength conversion pattern WCL1, the second wavelength conversion pattern WCL2 and the transparent pattern TPL.

The first capping layer CAP1 may include an inorganic material. For example, the first capping layer CAP1 may include at least one of: silicon nitride, aluminum nitride, zirconium nitride, titanium nitride, hafnium nitride, tantalum nitride, silicon oxide, aluminum oxide, titanium oxide, tin oxide, cerium oxide and silicon oxynitride.

The first light-blocking member BM1 may be disposed on the first capping layer CAP1. The first light-blocking member BM1 may be disposed in the blocking area BA of the display area DA along the boundary of the sub-pixel SPXn. The first light-blocking member BM1 may be disposed in an area between the wavelength control layer WCL and the transparent pattern TPL disposed in the light exit area LA.

The first light-blocking member BM1 may include an organic material. According to an embodiment of the disclosure, the first light-blocking member BM1 may include a light-absorbing material that absorbs light in the visible wavelength range. The first light-blocking member BM1 may include a light-absorbing material and may be disposed along the boundaries of the sub-pixels SPXn. Accordingly, the first light-blocking member BM1 may define the light exit areas LA: LA1, LA2 and LA3 and the blocking area BA of each of the sub-pixels SPXn. In other words, the first light-blocking member BM1 may be a subsidiary pixel-defining layer defining the light exit area LA and the blocking area BA of each of the sub-pixels SPXn.

The first planarization layer OC1 may be disposed on the wavelength control layer 800 and the first light-blocking member BM1. The first planarization layer OC1 may be disposed on the wavelength control layer 800 and the first light-blocking member BM1, to provide a flat surface over the underlying elements having different level differences. The first planarization layer OC1 may include an organic material. For example, the first planarization layer OC1 may be at least one of an acrylic resin, an epoxy resin, a phenol resin, a polyamide resin, and a polyimide resin.

The color filter layer CF may be disposed on the first planarization layer OC1 in the display area DA.

The color filter layer CF may include a first color filter CF1, a second color filter CF2, and a third color filter CF3.

The first to third color filters CF1, CF2 and CF3 may include a colorant such as a dye and a pigment that absorbs wavelengths other than a given color wavelength. The first color filter CF1 may selectively transmit light of the first color (e.g., red light) and may block and absorb light of the second color (e.g., green light) and light of the third color (e.g., blue light). The second color filter CF2 may selectively transmit light of the second color (e.g., green light) and may block and absorb light of the first color (e.g., red light) and light of the third color (e.g., blue light). The third color filter CF3 may selectively transmit light of the third color (e.g., blue light) and may block and absorb light of the first color (e.g., red light) and light of the second color (e.g., green light). For example, the first color filter CF1 may be a red color filter, the second color filter CF2 may be a green color filter, and the third color filter CF3 may be a blue color filter.

The first to third color filters CF1, CF2 and CF3 may absorb a part of the light introduced from the outside of the display device 10 to reduce reflection of external light. Accordingly, the first to third color filters CF1, CF2 and CF3 can prevent color distortion due to reflection of external light.

The first color filter CF1 may be disposed in the first light exit area LA1 of the first sub-pixel SPX1. The first color filter CF1 may be further disposed in the blocking area BA surrounding the light exit area LA. The first color filter CF1 may be disposed on the first planarization layer OC1 in the first light exit area LA1 and the blocking area BA.

The second color filter CF2 may be disposed in the second light exit area LA2 of the second sub-pixel SPX2. The second color filter CF2 may be further disposed in the blocking area BA surrounding the light exit area LA. The second color filter CF2 may be disposed on the first planarization layer OC1 exposed by the first color filter CF1 in the second light exit area LA2 and may be disposed on the first color filter CF1 in the blocking area BA.

The third color filter CF3 may be disposed in the third light exit area LA3 of the third sub-pixel SPX3. The third color filter CF3 may be further disposed in the blocking area BA surrounding the light exit area LA. The third color filter CF3 may be disposed on the first planarization layer OC1 exposed by the first and second color filters CF1 and CF2 in the third light exit area LA3 and may be disposed on the first and second color filters CF1 and CF2 in the blocking area BA.

The passivation layer OC2 may be disposed on the color filter layer CF. The passivation layer OC2 may include at least one organic film to protect other elements disposed under the passivation layer OC2 from foreign substances such as dust.

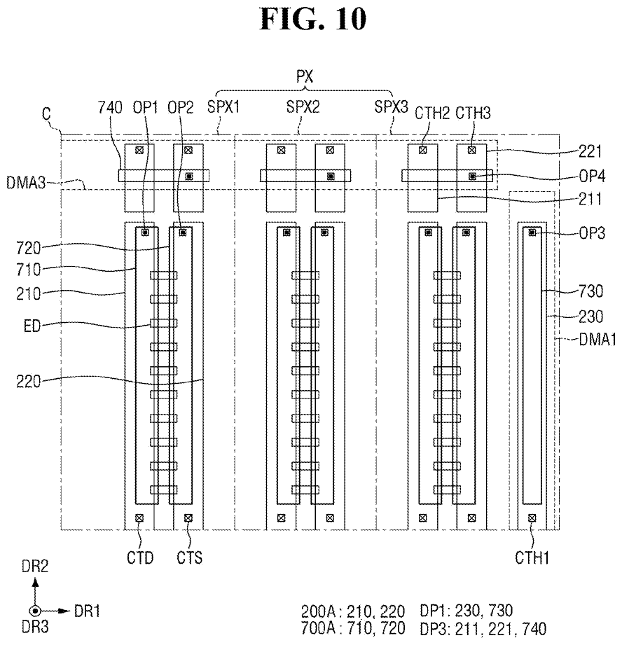

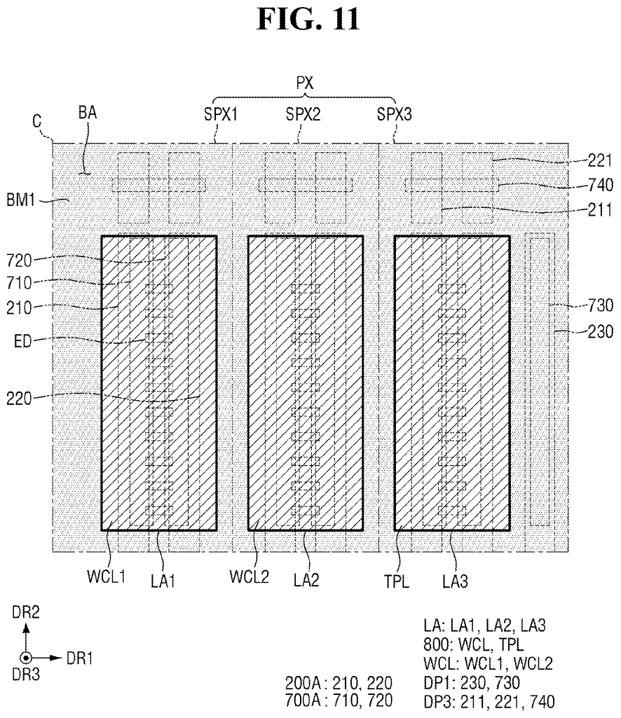

FIG. 10 is an enlarged plan view showing an example of a layout of area C of FIG. 6. FIG. 11 is a plan view showing a wavelength control layer and a first light-blocking member disposed in one pixel shown in FIG. 10.

FIGS. 10 and 11 show a planar structure of one pixel PX disposed in the display area DA adjacent to the non-display area NDA of the display device 10. FIGS. 10 and 11 show only the first dummy pattern DP1 disposed in the first heat dissipation dummy area DMA1 and the third dummy pattern DP3 disposed in the third heat dissipation dummy area DMA3. The second dummy pattern DP2 may have substantially the same planar structure as that of the first dummy pattern DP1 except for the location where it is disposed. The fourth dummy pattern DP4 may have substantially the same planar structure as that of the third dummy pattern DP3 except for the location where it is disposed. Therefore, in the following description, the planar structures of the first dummy pattern DP1 and the third dummy pattern DP3 disposed at the outermost positions of the display area DA of the display device 10 will be described. The structure of the second dummy pattern DP2 is substantially identical to the structure of the first dummy pattern DP1, and the structure of the fourth dummy pattern DP4 is substantially identical to the structure of the third dummy pattern DP3; and, therefore, the redundant descriptions will be omitted.

Referring to FIGS. 6, 10 and 11, the first dummy pattern DP1 may be disposed in the first heat dissipation dummy area DMA1. As described above, the first heat dissipation dummy area DMA1 may be disposed between the third light exit area LA3 of the pixel PX located at the rightmost position of the display area DA and the non-display area NDA.

The first dummy pattern DP1 may include a first layer 230 and a second layer 730 disposed on different layers.

The first layer 230 of the first dummy pattern DP1 may have a shape extended in the second direction DR2 when viewed from the top. The first layer 230 of the first dummy pattern DP1 may be disposed to face the electrode layer 200A and spaced apart from it in the first direction DR1.

The first layer 230 of the first dummy pattern DP1 may have the same shape as one of the first electrode 210 and the second electrode 220 of the electrode layer 200A when viewed from the top. The first layer 230 of the first dummy pattern DP1 may be disposed in the same shape as one of the first electrode 210 and the second electrode 220 of the electrode layer 200A when viewed from the top. The first layer 230 of the first dummy pattern DP1 may be in contact with at least one of the plurality of conductive layers (or metal layers) of the pixel element layer CCL through a first dummy electrode contact hole CTH1.

The second layer 730 of the first dummy pattern DP1 may have a shape extended in the second direction DR2 when viewed from the top (i.e., in a plan view). The second layer 730 of the first dummy pattern DP1 may be disposed to face the electrode layer 700A and spaced apart from it in the first direction DR1.

The second layer 730 of the first dummy pattern DP1 may have the same shape as one of the first contact electrode 710 and the second contact electrode 720 of the contact electrode 700A when viewed from the top. The second layer 730 of the first dummy pattern DP1 may be disposed in the same pattern as one of the first contact electrode 710 and the second contact electrode 720 of the contact electrode 700A.

The second layer 730 of the first dummy pattern DP1 may be disposed on the first layer 230 of the first dummy pattern DP1. The second layer 730 of the first dummy pattern DP1 may overlap at least a part of the first layer 230 in the third direction DR3. The second layer 730 of the first dummy pattern DP1 may be in contact with a part of the first layer 230 of the first dummy pattern DP1 through a third contact opening OP3.

According to an embodiment of the disclosure, the first dummy pattern DP1 may be similar to the pattern of the electrode layer 200A and the contact electrode 700A which are disposed in the light exit area LA of each sub-pixel SPXn and form a pixel pattern. Specifically, the first and second electrodes 210 and 220 of the electrode layer 200A and the first and second contact electrodes 710 and 720 of the contact electrode 700A may be disposed in the light exit area LA of each sub-pixel SPXn, to form the pixel pattern. In such case, the first dummy pattern DP1 may correspond to the first electrode 210 and the first contact electrode 710 forming the pixel pattern, and may have the same pattern as the first electrode 210 and the first contact electrode 710. It should be understood that the disclosure is not limited thereto. The first dummy pattern DP1 may correspond to the second electrode 220 and the second contact electrode 720 forming the pixel pattern, and may have the same pattern as the second electrode 220 and the second contact electrode 720.

The wavelength control layer 800 disposed in the light exit area LA may not overlap with the first layer 230 of the first dummy pattern DP1 and the second layer 730 of the first dummy pattern DP1 in the third direction DR3. The first light-blocking member BM1 disposed in the blocking area BA may overlap the first layer 230 of the first dummy pattern DP1 and the second layer 730 of the first dummy pattern DP1 in the third direction DR3.

The third dummy pattern DP3 may be disposed in the third heat dissipation dummy area DMA3. As described above, the third heat dissipation dummy area DMA3 may be disposed between the first to third light exit areas LA1, LA3 and LA3 of the pixel PX located at the uppermost positions of the display area DA and the non-display area NDA.

The third dummy pattern DP3 may include first layers 211 and 221 and a second layer 740 disposed on different layers.

The first layers 211 and 221 of the third dummy pattern DP3 may have a shape extended in the second direction DR2 when viewed from the top (i.e., in a plan view). The first layers 211 and 221 of the third dummy pattern DP3 may not be disposed in the non-display area NDA. The first layers 211 and 221 of the third dummy pattern DP3 may be disposed to face the electrode layer 200A and spaced apart from it in the second direction DR2.

The first layer 211 and 221 of the third dummy pattern DP3 may include a first pattern 211 and a second pattern 221 spaced apart from each other. The first pattern 211 of the third dummy pattern DP3 and the second pattern 221 of the third dummy pattern DP3 may be spaced apart from each other in the first direction DR1.

The first pattern 211 of the third dummy pattern DP3 may be located on a virtual extension line of the first electrode 210, and the second pattern 221 of the third dummy pattern DP3 may be located on a virtual extension line of the second electrode 220. The first pattern 211 of the third dummy pattern DP3 and the first electrode 210 having such shapes may be formed via a disconnecting process at the separation region ROP after the process of disposing the light-emitting diodes ED during the process of fabricating the display device 10. Likewise, the second pattern 221 of the third dummy pattern DP3 and the second electrode 220 having such shapes may be formed via a disconnecting process at the separation region ROP after the process of disposing the light-emitting diodes ED during the process of fabricating the display device 10.

The first pattern 211 of the third dummy pattern DP3 may be in contact with at least one of the plurality of conductive layers (or metal layers) of the pixel element layer CCL through a second dummy electrode contact hole CTH2, and the second pattern 221 of the third dummy pattern DP3 may be in contact with at least one of the plurality of conductive layers (or metal layers) of the pixel element layer CCL through a third dummy electrode contact hole CTH3. Although both the first pattern 211 of the third dummy pattern DP3 and the second pattern 221 of the third dummy pattern DP3 are in contact with the circuit element layer CCL in the drawings, the disclosure is not limited thereto. For example, one of the first pattern 211 of the third dummy pattern DP3 and the second pattern 221 of the third dummy pattern DP3 may be in contact with the circuit element layer CCL, and the other pattern the first pattern 211 of the third dummy pattern DP3 and the second pattern 221 of the third dummy pattern DP3 may not be in contact with the circuit element layer CCL.

The second layer 740 of the third dummy pattern DP3 may have a shape extended in the first direction DR1 when viewed from the top (i.e., in a plan view). The second layer 740 of the third dummy pattern DP3 may cover the first pattern 211 and the second pattern 221 of the third dummy pattern DP3 in the second direction DR2. The second layer 740 of the third dummy pattern DP3 may be disposed to be spaced apart from the contact electrode 700A in the second direction DR2.

The second layer 740 of the third dummy pattern DP3 may be disposed on the first layers 211 and 221 of the third dummy pattern DP3. The second layer 740 of the third dummy pattern DP3 may overlap at least a part of the first layers 211 and 221 of the third dummy pattern DP3 in the third direction DR3. The second layer 740 of the third dummy pattern DP3 may be in contact with a part of the first layers 211 and 221 of the third dummy pattern DP3 through a fourth contact opening OP4. Although the second layer 740 of the third dummy pattern DP3 may be in contact with a part of the second pattern 221 of the third dummy pattern DP3 through the fourth contact opening OP4. For example, the second layer 740 of the third dummy pattern DP3 may be in contact with a part of the first pattern 211 of the third dummy pattern DP3, and with both of the first pattern 211 and the second pattern 221 of the third dummy pattern DP3.

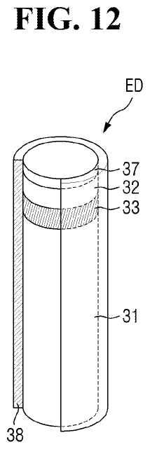

FIG. 12 is a view showing a light-emitting element according to an embodiment of the disclosure.

Referring to FIG. 12, the light-emitting diode ED is a particulate element, and may have a rod-like or cylindrical shape having a predetermined aspect ratio. The length of the light-emitting diode ED may be larger than the diameter of the light-emitting diode ED, and the aspect ratio according to the invention may range from, but is not limited to, 6:5 to 100:1.

The light-emitting diodes ED may have a size of a nanometer scale (from 1 nm to 1 micrometers (μm)) to a micrometer scale (from 1 μm to 1 millimeters (mm)). According to an embodiment of the disclosure, both of the diameter and length of the light-emitting diode ED may have nanometer scales or micrometer scales. In some other embodiments, the diameter of the light-emitting diode ED may have a nanometer scale, while the length of the light-emitting diode ED may have a micrometer scale. In some embodiments, the diameter and/or length of some of the light-emitting elements ED may have nanometer scales, while the diameter and/or length of some others of the light-emitting diodes ED have micrometer scales.

According to an embodiment of the disclosure, the light-emitting diode ED may be an inorganic light-emitting diode. The inorganic light-emitting diode may include a plurality of semiconductor layers. For example, the inorganic light-emitting diode may include a first conductivity type (e.g., n-type) semiconductor layer, a second conductivity type (e.g., p-type) semiconductor layer, and an active semiconductor layer interposed therebetween. The active semiconductor layer may receive holes and electrons from the first conductivity-type semiconductor layer and the second conductivity-type semiconductor layer, respectively, and the holes and electrons reaching the active semiconductor layer may be combined to emit light.

According to an embodiment of the disclosure, the above-described semiconductor layers may be sequentially stacked along the longitudinal direction of the light-emitting diode ED. The light-emitting diode ED may include a first semiconductor layer 31, an active layer 33 and a second semiconductor layer 32 sequentially stacked in the longitudinal direction.

The first semiconductor layer 31 may be doped with a first conductivity type dopant. The first conductivity type dopant may be Si, Ge, Sn, etc. According to an embodiment of the disclosure, the first semiconductor layer 31 may be n-GaN doped with n-type Si.

The second semiconductor layer 32 may be spaced apart from the first semiconductor layers 31 with the active layer 33 therebetween. The second semiconductor layer 32 may be doped with a second conductivity-type dopant such as Mg, Zn, Ca, Se and Ba. According to an embodiment of the disclosure, the second semiconductor layer 32 may be p-GaN doped with p-type Mg.

The active layer 33 may include a material having a single or multiple quantum well structure. As described above, the active layer 33 may emit light as electron-hole pairs are combined therein in response to an electrical signal applied through the first semiconductor layer 31 and the second semiconductor layer 32.

In some embodiments, the active layer 33 may have a structure in which a semiconductor material having a large band gap energy and a semiconductor material having a small band gap energy are alternately stacked on one another, and may include other Group III to Group V semiconductor materials depending on the wavelength range of the emitted light.

The light emitted from the active layer 33 may exit not only through the outer surfaces of the light-emitting diode ED in the longitudinal direction but also through both side surfaces. That is to say, the directions in which the light emitted from the active layer 33 propagates according to the invention are not limited to one direction.

The light-emitting diode ED may further include an element electrode layer 37 disposed on the second semiconductor layer 32. The element electrode layer 37 may be in contact with the second semiconductor layer 32. The element electrode layer 37 may be an ohmic contact electrode, but the invention is not limited to it. It may be a Schottky contact electrode.

When the both ends of the light-emitting diode ED are electrically connected to the contact electrodes 700A to apply electric signals to the first and second semiconductor layers 31 and 32, the element electrode layer 37 may be disposed between the second semiconductor layer 32 and the contact electrodes 700A to reduce the resistance. The element electrode layer 37 may include at least one of aluminum (Al), titanium (Ti), indium (In), gold (Au), silver (Ag), indium tin oxide (“ITO”), indium zinc oxide (“IZO”) and indium tin-zinc oxide (“ITZO”). The element electrode layer 37 may include a semiconductor material doped with n-type or p-type impurities.

The light-emitting diode ED may further include an insulating film 38 surrounding the outer peripheral surfaces of the first semiconductor layer 31, the second semiconductor layer 32, the active layer 33 and/or the element electrode layer 37. The insulating film 38 may be disposed to surround at least the outer surface of the active layer 33, and may be extended in a direction in which the light-emitting diode ED is extended. The insulating film 38 can protect the above-described elements. The insulating film 38 may be made of or include materials having insulating properties and can prevent an electrical short-circuit that may occur when the active layer 33 comes in contact with an electrode through which an electric signal is transmitted to the light-emitting diode ED. In addition, since the insulating film 38 includes the active layer 33 to protect the outer peripheral surfaces of the first and second semiconductor layers 31 and 32, it is possible to prevent a decrease in luminous efficiency.

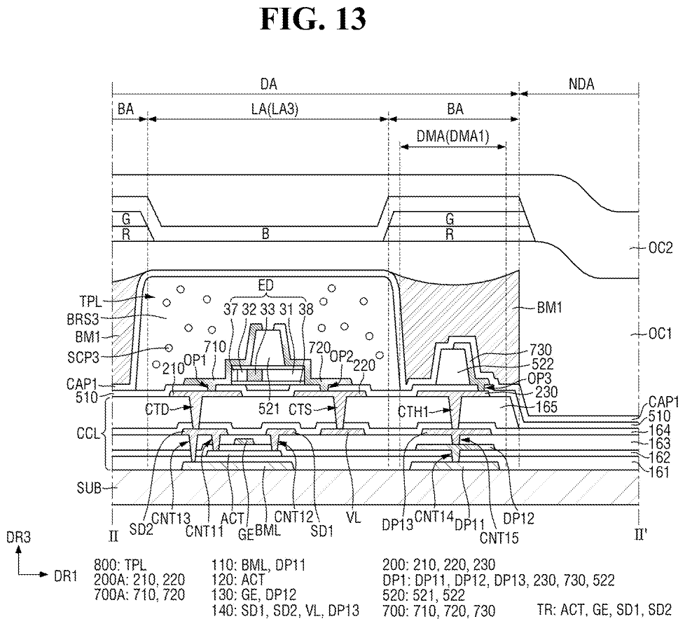

FIG. 13 is a cross-sectional view showing an example, taken along line II-II′ of the tiled display of FIG. 6.

FIG. 13 shows a non-display area NDA and a display area DA adjacent to the non-display area NDA of the display device 10. Specifically, the display area DA of FIG. 13 shows the light exit area LA as well as the first heat dissipation dummy areas DMA1.

Referring to FIG. 13, the circuit element layer CCL may be disposed on the substrate SUB. The circuit element layer CCL may include a bottom metal layer 110, a semiconductor layer 120, a first conductive layer 130, a second conductive layer 140, and a plurality of insulating films. The plurality of insulating films included in the circuit element layer CCL may include a buffer layer 161, a gate insulator 162, an interlayer dielectric film 163, a passivation layer 164, and a via-layer 165.

The bottom metal layer 110 is disposed on the substrate SUB. The bottom metal layer 110 may be located in the display area DA. The bottom metal layer 110 may include a light-blocking layer BML and a first heat dissipation pattern DP11.

The light-blocking layer BML may be disposed at least under a channel region of an active layer ACT of a transistor TR to cover it in a plan view. It is, however, to be understood that the disclosure is not limited thereto. In some implementations, the light-blocking layer BML may be eliminated.

The first heat dissipation pattern DP11 may be spaced apart from the light-blocking layer BML. The first heat dissipation pattern DP11 may be disposed in the first heat dissipation dummy area DMA1. The first heat dissipation pattern DP11 may be one of a plurality of layers forming the first dummy pattern DP1. In the following description, the same reference numeral DP11 may be given to the first heat dissipation pattern DP11 as well as the third layer DP11 of the first dummy pattern DP1. The third layer DP11 of the first dummy pattern DP1 may be disposed under the first layer 230 of the first dummy pattern DP1 and the second layer 730 of the first dummy pattern DP1.

The bottom metal layer 110 may include a material that blocks light. For example, the bottom metal layer 110 may be made of or include an opaque metal material that blocks light transmission.

The buffer layer 161 may be disposed over the bottom metal layer 110. The buffer layer 161 may be disposed to cover the entire surface of the substrate SUB on which the bottom metal layer 110 is disposed. The buffer layer 161 may be disposed across the display area DA and the non-display area NDA on the substrate SUB. The buffer layer 161 can protect a plurality of transistors from moisture permeating through the substrate SUB which is vulnerable to moisture permeation.

The semiconductor layer 120 is disposed on the buffer layer 161. The semiconductor layer 120 may be disposed in the display area DA. The semiconductor layer 120 may include the active layer ACT of the transistor TR. The active layer ACT of the transistor TR may be disposed to overlap the light-blocking layer BML in a plan view as described above.

The semiconductor layer 120 may include polycrystalline silicon, monocrystalline silicon, an oxide semiconductor, etc. According to an embodiment of the disclosure, when the semiconductor layer 120 includes polycrystalline silicon, the polycrystalline silicon may be formed by crystallizing amorphous silicon. When the semiconductor layer 120 contains polycrystalline silicon, the active layer ACT of the transistor TR may include a plurality of doped regions doped with impurities, and a channel region between them. In another embodiment, the semiconductor layer 120 may include an oxide semiconductor. For example, the oxide semiconductor may be indium-tin oxide (ITO), indium-zinc oxide (IZO), indium-gallium oxide (“IGO”), indium-zinc-tin oxide (IZTO), indium-gallium-zinc oxide (“IGZO”), indium-gallium-tin oxide (“IGTO”), indium-gallium-zinc-tin oxide (“IGZTO”), etc.

The gate insulator 162 may be disposed on the semiconductor layer 120. The gate insulator 162 may be disposed across the display area DA and the non-display area NDA. The gate insulator 162 may work as a gate insulating layer of each transistor. The gate insulator 162 may be made up of multiple layers in which inorganic layers including inorganic material, e.g., at least one of silicon oxide (SiOx), silicon nitride (SiNx) and silicon oxynitride (SiOxNy) are stacked on one another alternately.

The first conductive layer 130 may be disposed on the gate insulator 162. The first conductive layer 130 may be located in the display area DA. The first conductive layer 130 may include the gate electrode GE of the transistor TR and a second heat dissipation pattern DP12.

The gate electrode GE of the transistor TR may be disposed so that it overlaps the channel region of the active layer ACT1 in the thickness direction of the substrate SUB, i.e., in the third direction DR3.

The second heat dissipation pattern DP12 may be spaced apart from the gate electrode GE. The second heat dissipation pattern DP12 may be disposed in the first heat dissipation dummy area DMA1. The second heat dissipation pattern DP12 may overlap with the first heat dissipation pattern DP11 in a plan view. The second heat dissipation pattern DP12 may be in direct contact with one surface (e.g., upper surface) of the first heat dissipation pattern DP11 through a contact hole CNT14 penetrating the buffer layer 161 and the gate insulator 162. The second heat dissipation pattern DP12 may be one of a plurality of layers forming the first dummy pattern DP1. In the following description, the same reference numeral DP12 may be given to the second heat dissipation pattern DP12 as well as the fourth layer DP12 of the first dummy pattern DP1. It is, however, to be understood that the disclosure is not limited thereto. The second heat dissipation pattern DP12 may be eliminated in another embodiment.

The first conductive layer 130 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof. It is, however, to be understood that the disclosure is not limited thereto.

The interlayer dielectric film 163 may be disposed on the first conductive layer 130. The interlayer dielectric film 163 may be disposed across the display area DA and the non-display area NDA. The interlayer dielectric film 163 may cover the gate electrode GE. The interlayer dielectric film 163 may include inorganic insulating materials such as silicon oxide (SiOx), silicon nitride (SiNx), and silicon oxynitride (SiOxNy).

The second conductive layer 140 may be disposed on the first interlayer dielectric film 163. The second conductive layer 140 may be located in the display area DA. The second conductive layer 140 may include a drain electrode SD1 of the transistor TR, a source electrode SD2 of the transistor TR, a voltage line VL, and a third heat dissipation pattern DP13.

The drain electrode SD1 of the transistor TR may be electrically connected to one end region of the active layer ACT of the transistor TR through a contact hole CNT12 penetrating the interlayer dielectric film 163 and the gate insulator 162.

The drain electrode SD2 of the transistor TR may be electrically connected to the other end region of the active layer ACT of the transistor TR through a contact hole CNT11 penetrating the interlayer dielectric film 163 and the gate insulator 162. In addition, the source electrode SD2 of the transistor TR may be electrically connected to the light-blocking layer BML through another contact hole CNT13 penetrating through the interlayer dielectric film 163, the gate insulator 162, and the buffer layer 161.

A low-level voltage (or second supply voltage) lower than a high-level voltage (or first supply voltage) supplied to the transistor TR may be applied to the voltage line VL. The voltage line VL may be electrically connected to the second electrode 220 through the second electrode contact hole CTS penetrating the passivation layer 164 and the via-layer 165 to be described later.

The third heat dissipation pattern DP13 may be spaced apart from the drain electrode SD1 of the transistor TR, the source electrode SD2 of the transistor TR, and the voltage line VL. The third heat dissipation pattern DP13 may be disposed in the first heat dissipation dummy area DMA1. The third heat dissipation pattern DP13 may be disposed to overlap the second heat dissipation pattern DP12 and the first heat dissipation pattern DP11 in a plan view. The third heat dissipation pattern DP13 may be in direct contact with one surface (e.g., upper surface) of the second heat dissipation pattern DP12 through a contact hole CNT15 penetrating the interlayer dielectric film 163.

The third heat dissipation pattern DP13 may be one of a plurality of layers forming the first dummy pattern DP1. In the following description, the same reference numeral DP13 may be given to the third heat dissipation pattern DP13 as well as the fifth layer DP13 of the first dummy pattern DP1. As described above, when the second heat dissipation pattern DP12 is eliminated, the third heat dissipation pattern DP13 may be in direct contact with the first heat dissipation pattern DP11 through a contact hole penetrating the interlayer dielectric film 163, the gate insulator 162 and the buffer layer 161.

The second conductive layer 140 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof. It is, however, to be understood that the disclosure is not limited thereto.

The passivation layer 164 may be disposed on the second conductive layer 140. The passivation layer 164 may be disposed across the display area DA and the non-display area NDA. The passivation layer 164 covers and protects the second conductive layer 140. The passivation layer 164 may include inorganic insulating materials such as silicon oxide (SiOx), silicon nitride (SiNx), and silicon oxynitride (SiOxNy).

The via-layer 165 may be disposed on the passivation layer 164. The via-layer 165 may be disposed in the display area DA. The via-layer 165 may not be disposed in the non-display area NDA. The via-layer 165 may provide a flat, upper surface over the patterns of the elements thereunder having different levels. The via-layer 165 may include an organic insulating material, for example, an organic material such as polyimide (“PI”).

Referring to FIGS. 10 to 13, the light-emitting element layer may be disposed on one surface (e.g., upper surface) of the via-layer 165 of the circuit element layer CCL. The light-emitting element layer may include a third conductive layer 200, a second insulating layer 510, a light-emitting diode ED, a first insulating layer 520, and a fourth conductive layer 700.

The third conductive layer 200 may be disposed on one surface (e.g., upper surface) of the via-layer 165. The third conductive layer 200 may be located in the display area DA. The third conductive layer 200 may include the electrode layer 200A and a fourth heat dissipation pattern 230. In the following description, the same reference numeral 230 may be given to the fourth heat dissipation pattern 230 as well as the first layer 230 of the first dummy pattern DP1.

The electrode layer 200A may be disposed directly on one surface (e.g., upper surface) of the via-layer 165. As described above, the electrode layer 200A may include the first electrode 210 and the second electrode 220, and the first electrode 210 and the second electrode 220 may be spaced apart from each other on the surface of the via-layer 165. The first electrode 210 and the second electrode 220 may be spaced apart from each other in the first direction DR1 to expose a part of the via-layer 165.

The first electrode 210 may be connected to the transistor TR through the first electrode contact hole CTD penetrating the via-layer 165 and the passivation layer 164. Specifically, the first electrode 210 may be connected to the source electrode SD2 of the transistor TR through the first electrode contact hole CTD. The first electrode 210 may be in direct contact with one surface (e.g., upper surface) of the source electrode SD2 of the transistor TR exposed by the first electrode contact hole CTD.

The second electrode 220 may be connected to the voltage line VL through the second electrode contact hole CTS penetrating the via-layer 165 and the passivation layer 164. The second electrode 220 may be in direct contact with one surface (e.g., upper surface) of the voltage line VL exposed by the second electrode contact hole CTS.

The fourth heat dissipation pattern 230 may be spaced apart from the first electrode 210 and the second electrode 220. The fourth heat dissipation pattern 230 may be disposed in the first heat dissipation dummy area DMA1. The fourth heat dissipation pattern 230 may be disposed to overlap the first to third heat dissipation patterns DP11, DP12 and DP13 in a plan view. The fourth heat dissipation pattern 230 may be in direct contact with one surface (e.g., upper surface) of the third heat dissipation pattern DP13 through the first dummy electrode contact hole CTH1 penetrating the via-layer 165 and the passivation layer 164.

The fourth heat dissipation pattern 230 may be one of a plurality of layers forming the first dummy pattern DP1. The fourth heat dissipation pattern 230 may be the first layer 230 of the first dummy pattern DP1 described above with reference to FIGS. 10 and 11. Although the fourth heat dissipation pattern 230 disposed on the via-layer 165 is in direct contact with the third heat dissipation pattern DP13 of the second conductive layer 140 included in the circuit element layer CCL in the drawings, the disclosure is not limited thereto. In another embodiment, for example, the fourth heat dissipation pattern 230 may be in direct contact with the second heat dissipation pattern DP12 of the first conductive layer 130 included in the circuit element layer CCL while the third heat dissipation pattern DP13 is eliminated, or may be in direct contact with the first heat dissipation pattern DP11 of the bottom metal layer 110 while the second and third heat dissipation pattern DP12 and DP13 are eliminated.

The first electrode 210, the second electrode 220 and the fourth heat dissipation pattern 230 may be made of or include the same material. The first electrode 210, the second electrode 220 and the fourth heat dissipation pattern 230 may be disposed in the same layer. Specifically, the first electrode 210, the second electrode 220 and the fourth heat dissipation pattern 230 may be simultaneously formed via a single mask process. As described above, the fourth heat dissipation pattern 230 may be formed in the same pattern as one of the first electrode 210 and the second electrode 220.

The third conductive layer 200 may include a transparent conductive material. For example, the third conductive layer 200 according to the invention may include, but is not limited to, a material such as indium tin oxide (ITO), indium zinc oxide (IZO) and indium tin zinc oxide (ITZO). In some other embodiments, the third conductive layer 200 may include a conductive material having high reflectivity. For example, the third conductive layer 200 may include a metal material such as silver (Ag), copper (Cu) and aluminum (Al) as the material having high reflectivity. The third conductive layer 200 may have a structure in which one or more layers of a transparent conductive material and a metal layer having high reflectivity are stacked on one another, or may be made up of multiple layers including them. In an embodiment, the third conductive layer 200 may have a stack structure of ITO/silver (Ag)/ITO, ITO/Ag/IZO or ITO/Ag/ITZO/IZO, or may be an alloy including aluminum (Al), nickel (Ni), lanthanum (La), etc.

The second insulating layer 510 may be disposed on the third conductive layer 200. The second insulating layer 510 may be disposed across the display area DA and the non-display area NDA. The second insulating layer 510 may be disposed to cover the third conductive layer 200.

The second insulating layer 510 can protect the first electrode 210, the second electrode 220 and the fourth heat dissipation pattern 230 and can insulate them from each other. In addition, the second insulating layer 510 can prevent that the light-emitting diodes ED disposed on it are brought into contact with other elements and damaged.

The second insulating layer 510 may be disposed on the third conductive layer 200 to expose at least a part of the third conductive layer 200. A plurality of contact openings OP1, OP2 and OP3 penetrating the second insulating layer 510 may be defined in the second insulating layer 510. The plurality of contact openings OP1, OP2 and OP3 may be defined by sidewalls of the second insulating layer 510. The first contact opening OP1 may expose one surface (e.g., upper surface) of the first electrode 210, the second contact opening OP2 may expose one surface (e.g., upper surface) of the second electrode 220, and the third contact opening OP3 may expose one surface (e.g., upper surface) of the fourth heat dissipation pattern 230.

The light-emitting diodes ED may be disposed on the second insulating layer 510. The plurality of light-emitting diodes ED may be disposed in the light exit areas LA. The plurality of light-emitting diodes ED may not be disposed in the blocking area BA.

The light-emitting diodes ED may be disposed between the first electrode 210 and the second electrode 220 in the light exit areas LA. As described above, the light-emitting diodes ED may have a shape extended in a direction, and may be aligned so that their both ends are placed on the first electrode 210 and the second electrode 220, respectively.

The light-emitting diode ED may be aligned so that the direction in which they are extended is substantially parallel to one surface of the substrate SUB. The first semiconductor layer 31, the active layer 33, the second semiconductor layer 32 and the element electrode layer 37 of each of the light-emitting diodes ED may be sequentially disposed parallel to the surface of the substrate SUB in the cross section passing through the both ends.

The first insulating layer 520 may be disposed on the light-emitting diodes ED and the second insulating layer 510 on which the light-emitting diodes ED are disposed. The first insulating layer 520 may include the fixed pattern 521 and a fifth heat dissipation pattern 522.

The fixed pattern 521 may be disposed in the light exit areas LA. The fixed pattern 521 may be disposed on the light-emitting diodes ED in the light exit areas LA. The fixed pattern 521 may be disposed to expose both ends of the light-emitting diodes ED. The fixed pattern 521 can protect the light-emitting diodes ED and fix the light-emitting diodes ED during the process of fabricating the display device 10. Although not shown in the drawings, the material forming the fixed pattern 521 may be located between the first electrode 210 and the second electrode 220, and the recessed empty space between the second insulating layer 510 and the light-emitting diodes ED may be filled with the material.

The fifth heat dissipation pattern 522 may be spaced apart from the fixed pattern 521. The fifth heat dissipation pattern 522 may be disposed in the first heat dissipation dummy area DMA1. The fifth heat dissipation pattern 522 may be disposed to overlap the fourth heat dissipation pattern 230, but may not overlap the third contact opening OP3 in a plan view. The fifth heat dissipation pattern 522 may be disposed to have a predetermined thickness in the first heat dissipation dummy area DMA1 located between the non-display area NDA and the light exit areas LA to form the first dummy pattern DP1. The fifth heat dissipation pattern 522 may serve as a heat shield barrier to block heat generated outside the non-display area NDA and diffused to the light exit area LA during the process of cutting the display device 10.

The fixed pattern 521 and the fifth heat dissipation pattern 522 may have the same shape. The fixed pattern 521 and the fifth heat dissipation pattern 522 may have the same thickness. The fixed pattern 521 and the fifth heat dissipation pattern 522 may be made of or include the same material. The fixed pattern 521 and the fifth heat dissipation pattern 522 may be disposed in the same layer. That is to say, the fixed pattern 521 and the fifth heat dissipation pattern 522 may be simultaneously formed via a single mask process.

The fifth heat dissipation pattern 522 may be one of a plurality of layers forming the first dummy pattern DP1. The fifth heat dissipation pattern 522 may be a sixth layer 522 of the dummy pattern DP1. In the following description, the same reference numeral 522 may be given to the fifth heat dissipation pattern 522 as well as the sixth layer 522 of the first dummy pattern DP1.

The first insulating layer 520 according to the invention may include, but is not limited to, an organic insulating material such as polyimide (PI).

The fourth conductive layer 700 may be disposed on the first insulating layer 520. The fourth conductive layer 700 may be located in the display area DA. The fourth conductive layer 700 may include the contact electrodes 700A and a sixth heat dissipation pattern 730.

The contact electrodes 700A may be disposed in the light exit areas LA. As described above, the contact electrodes 700A may include the first contact electrode 710 and the second contact electrode 720 spaced apart from each other. The first contact electrode 710 and the second contact electrode 720 may be spaced apart from each other on the fixed pattern 521.

The first contact electrode 710 may be in contact with the first ends of the light-emitting diodes ED and the first electrode 210. The first contact electrode 710 may be in contact with the first ends of the light-emitting diodes ED exposed by the fixed pattern 521. In addition, the first contact electrode 710 may be in contact with a surface of the first electrode 210 exposed by the first contact opening OP1 penetrating the second insulating layer 510. As the first contact electrode 710 is in contact with the first ends of the light-emitting diodes ED and the first electrode 210, the electric signal applied to the first electrode 210 can be transmitted to the first ends of the light-emitting diodes ED through the first contact electrode 710.

The second contact electrode 720 may be in contact with the second ends of the light-emitting diodes ED and the second electrode 220. The second contact electrode 720 may be in contact with the second ends of the light-emitting diodes ED exposed by the fixed pattern 521. In addition, the second contact electrode 720 may be in contact with a surface of the second electrode 220 exposed by the second contact opening OP2 penetrating the second insulating layer 510. As the second contact electrode 720 is in contact with the second ends of the light-emitting diodes ED and the second electrode 220, the electric signal applied to the second electrode 220 can be transmitted to the second ends of the light-emitting diodes ED through the second contact electrode 720.

The sixth heat dissipation pattern 730 may be spaced apart from the contact electrodes 700A. In the following description, the same reference numeral 730 may be given to the sixth heat dissipation pattern 730 as well as the second layer 730 of the first dummy pattern DP1. The sixth heat dissipation pattern 730 may be disposed in the first heat dissipation dummy area DMA1. The sixth heat dissipation pattern 730 may be disposed on the fourth heat dissipation pattern 230 and the fifth heat dissipation pattern 522. The sixth heat dissipation pattern 730 may be in direct contact with a surface of the fourth heat dissipation pattern 230 exposed by the third contact opening OP3 penetrating the second insulating layer 510.

The sixth heat dissipation pattern 730 may be one of a plurality of layers forming the first dummy pattern DP1. The sixth heat dissipation pattern 730 may be a second layer 730 of the first dummy pattern DP1 described above with reference to FIGS. 10 and 11.

The first contact electrode 710, the second contact electrode 720 and the sixth heat dissipation pattern 730 may be made of or include the same material. The first contact electrode 710, the second contact electrode 720 and the sixth heat dissipation pattern 730 may be disposed in the same layer. That is to say, the first contact electrode 710, the second contact electrode 720 and the sixth heat dissipation pattern 730 may be simultaneously formed via a single mask process. As described above, the sixth heat dissipation pattern 730 may be formed in the same pattern as one of the first contact electrode 710 and the second contact electrode 720.

The fourth conductive layer 700 may include a conductive material. For example, the fourth conductive layer 700 may include ITO, IZO, ITZO, aluminum (Al), etc. For example, the fourth conductive layer 700 according to the invention may include, but is not limited to, a transparent conductive material.

The wavelength control layer 800 may be located in the display area DA. The wavelength control layer 800 may be disposed in the light exit areas LA. As shown in the drawings, the transparent pattern TPL may be disposed to cover the electrode layer 200A, the light-emitting diodes ED, the fixed pattern 521 and the contact electrodes 700A disposed in the third light exit area LA3.

The first light-blocking member BM1 may be located in the display area DA. The first light-blocking member BM1 may be disposed in the blocking area BA. The first light-blocking member BM1 may be disposed to cover the fourth heat dissipation pattern 230, the fifth heat dissipation pattern 522 and the sixth heat dissipation pattern 730 disposed in the first heat dissipation dummy area DMA1.

The first planarization layer OC1 may be disposed on the wavelength control layer 800 and the first light-blocking member BM1. The first planarization layer OC1 may be disposed in the display area DA and the non-display area NDA.

The color filter layer CF may be disposed on the first planarization layer OC1. The color filter layer CF may be disposed in the display area DA.

The passivation layer OC2 may be disposed on the color filter layer CF. The passivation layer OC2 may be disposed in the display area DA and the non-display area NDA.

According to this embodiment, the electrode layer 200A, the fixed pattern 521 and the contact electrodes 700A may be disposed in the light exit area LA to form a pixel pattern. The first dummy pattern DP1 may be disposed in the first heat dissipation dummy area DMA1 and may include the first layer 230, the second layer 730 and the sixth layer 522 of the first dummy pattern DP1 formed in a pattern similar to the pixel pattern. Even though the additional pattern is disposed in the first heat dissipation dummy area DMA1, the additional pattern has a pattern similar to the pixel pattern and is disposed in the same layer as the plurality of layers forming the pixel pattern, and thus no additional mask process is desirable. Accordingly, the first dummy pattern DP1 capable of dissipating heat generated during the process of fabricating the display device 10 to be described later can be formed without any additional mask process, thereby preventing a decrease in the efficiency of the process of fabricating the display device 10.

The first dummy pattern DP1 disposed in the first heat dissipation dummy area DMA1 may have a stack structure including at least some of a plurality of layers (conductive layers) forming the light-emitting element layer or the circuit element layer. Specifically, the first dummy pattern DP1 may include a plurality of layers consisting of at least some of the bottom metal layer 110, the first conductive layer 130 and the second conductive layer 140 included in the circuit element layer CCL, and the third conductive layer 200 and the fourth conductive layer 700 included in the light-emitting element layer. For example, the first dummy pattern DP1 may include the first layer 230, the second layer 730, the third layer DP11, the fourth layer DP12 and the fifth layer DP13. At least one of the first to fifth layers 230, 730, DP11, DP12 and DP13 of the first dummy pattern DP1 may include a metal material. Also, the first to fifth layers 230, 730, DP11, DP12 and DP13 may be in direct contact with one another through at least one hole. As the first dummy pattern DP1 has a stack structure in which the layers made of or including a metal material having excellent thermal conductivity are in direct contact with each other through at least one hole, a heat dissipation path can be formed and the heat from the non-display area NDA can be released through it, which otherwise is transferred to the light exit area LA. As a result, heat transferred to the light exit area LA can be effectively reduced, and thus it is possible to prevent damage to a plurality of elements disposed in the light exit area LA, e.g., the wavelength control layer 800 by the heat.

The first dummy pattern DP1 disposed in the first heat dissipation dummy area DMA1 may further include the sixth layer 522 provided as an insulating layer forming the light-emitting element layer. Unlike the first to fifth layers 230, 730, DP11, DP12 and DP13 of the first dummy pattern DP1, the sixth layer 522 of the first dummy pattern DP1 may include an insulating material. The sixth layer 522 of the first dummy pattern DP1 may be disposed between the wavelength control layer 800 located in the outermost light exit area LA and the non-display area NDA, with a predetermined thickness. The sixth layer 522 of the first dummy pattern DP1 may work as a heat shield barrier. Accordingly, it is possible to efficiently block diffusion of heat from the non-display area NDA to the light exit area LA by virtue of the heat shield barrier.

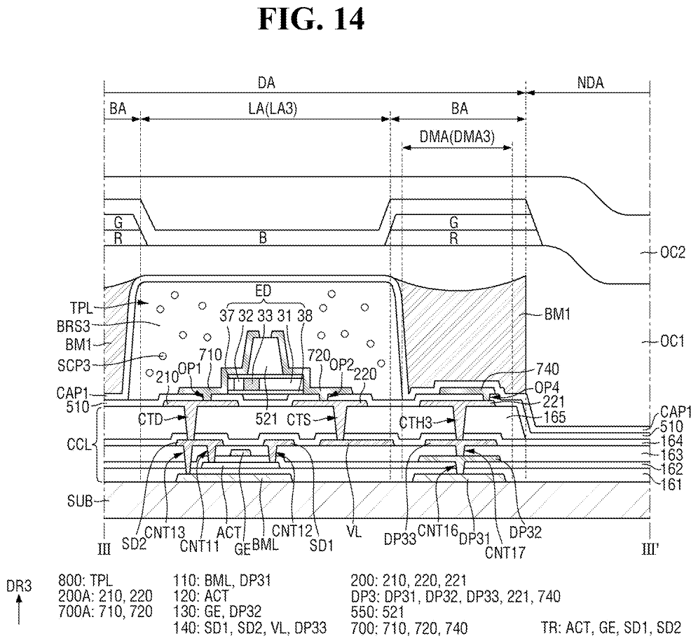

FIG. 14 is a cross-sectional view showing an example, taken along line III-III′ of the tiled display of FIG. 6.

FIG. 14 shows a non-display area NDA and a display area DA adjacent to the non-display area NDA of the display device 10. Specifically, the display area DA of FIG. 14 shows the light exit area LA as well as the third heat dissipation dummy areas DMA3.

Referring to FIGS. 10 to 12 and 14, the third dummy pattern DP3 may have a structure in which a plurality of layers is stacked. Specifically, the third dummy pattern DP3 may include the third layer DP31, the fourth layer DP32, the fifth layer DP33, the first layers 211 and 221, and the second layer 740.

The bottom metal layer 110 may further include a seventh heat dissipation pattern DP31 disposed in the third heat dissipation dummy area DMA3. The seventh heat dissipation pattern DP31 may be one of a plurality of layers forming the third dummy pattern DP3. The seventh heat dissipation pattern DP31 may be the third layer DP31 of the third dummy pattern DP3.

The first conductive layer 130 may further include an eighth heat dissipation pattern DP32 disposed in the third heat dissipation dummy area DMA3. The eighth heat dissipation pattern DP32 may be one of a plurality of layers forming the third dummy pattern DP3. The eighth heat dissipation pattern DP32 may be the fourth layer DP32 of the third dummy pattern DP3.

The eighth heat dissipation pattern DP32 may overlap with the seventh heat dissipation pattern DP31 in a plan view. The eighth heat dissipation pattern DP32 may be in direct contact with one surface (e.g., upper surface) of the seventh heat dissipation pattern DP31 through a contact hole CNT16 penetrating the buffer layer 161 and the gate insulator 162.

The second conductive layer 140 may further include a ninth heat dissipation pattern DP33 disposed in the third heat dissipation dummy area DMA3. The ninth heat dissipation pattern DP33 may be one of a plurality of layers forming the third dummy pattern DP3. The ninth heat dissipation pattern DP33 may be the fifth layer DP33 of the third dummy pattern DP3.

The ninth heat dissipation pattern DP33 may overlap the eighth heat dissipation pattern DP32 in a plan view. The ninth heat dissipation pattern DP33 may be in direct contact with one surface (e.g., upper surface) of the eighth heat dissipation pattern DP32 through a contact hole CNT17 penetrating the interlayer dielectric film 163.

The third conductive layer 200 may further include a tenth heat dissipation pattern 221 disposed in the third heat dissipation dummy area DMA3. Although not shown in the drawings, the third conductive layer 200 may further include another heat dissipation pattern 211 disposed in the third heat dissipation dummy area DMA3. The tenth heat dissipation pattern 221 may be one of a plurality of layers forming the third dummy pattern DP3. The tenth heat dissipation pattern 221 may be the second pattern 221 of the first layers 211 and 221 of the third dummy pattern DP3 described above with reference to FIGS. 10 and 11.

The tenth heat dissipation pattern 221 may overlap the ninth heat dissipation pattern DP33 in a plan view. The tenth heat dissipation pattern 221 may be in direct contact with one surface (e.g., upper surface) of the ninth heat dissipation pattern DP33 through the third dummy electrode contact hole CTH3 penetrating the via-layer 165 and the passivation layer 164.

The fourth conductive layer 700 may further include an eleventh heat dissipation pattern 740 disposed in the third heat dissipation dummy area DMA3. The eleventh heat dissipation pattern 740 may be one of a plurality of layers forming the third dummy pattern DP3. The eleventh heat dissipation pattern 740 may be the second layer 740 of the third dummy pattern DP3 described above with reference to FIGS. 10 and 11.

The eleventh heat dissipation pattern 740 may overlap with the tenth heat dissipation pattern 221 in a plan view. The eleventh heat dissipation pattern 740 may be in direct contact with a surface of the tenth heat dissipation pattern 221 exposed by the fourth contact opening OP4 penetrating the second insulating layer 510.

The third dummy pattern DP3 disposed in the third heat dissipation dummy area DMA3 may have a stack structure including at least some of a plurality of layers (conductive layers) forming the light-emitting element layer or the circuit element layer, similarly to the first dummy pattern DP1. It should be noted that the third dummy pattern DP3 may not include a heat dissipation pattern provided as the first insulating layer 520. Although the third dummy pattern DP3 does not include a pattern made of or including an insulating material and serving as a heat shield barrier, the third dummy pattern DP3 includes at least one layer made of or including a metal material, and thus it can have a heat dissipation path through the plurality of layers. As a result, heat transferred to the light exit area LA can be effectively reduced, and thus it is possible to prevent damage to a plurality of elements disposed in the light exit area LA, e.g., the wavelength control layer 800 by the heat.

Hereinafter, the structure of the display device 10 according to other embodiments will be described. In the following description, the same or similar elements will be denoted by the same or similar reference numerals, and redundant descriptions will be omitted or briefly described. Descriptions will focus on differences from the above embodiment.

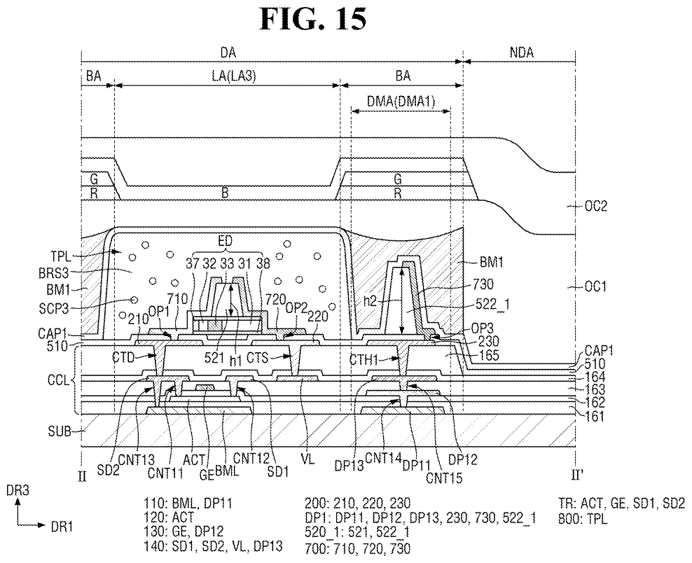

FIG. 15 is a cross-sectional view showing another example, taken along line II-II′ of the tiled display of FIG. 6.

A display device 10 according to this embodiment of FIG. 15 is different from the display device according to the embodiment of FIG. 13 in that a first insulating layer 520_1 includes a fifth heat dissipation pattern 522_1 and a fixed pattern 521 having different heights.

Specifically, the first insulating layer 520_1 may include a fixed pattern 521 and a fifth heat dissipation pattern 522_1 disposed in the display area DA. The fixed pattern 521 may be disposed in the light exit area LA, and the fifth heat dissipation pattern 522_1 may be disposed in the first heat dissipation dummy area DMA′.

The fixed pattern 521 may be disposed on the light-emitting diode ED in the light exit area LA. The fixed pattern 521 may be disposed on the light-emitting diode ED with a first thickness h1. The first thickness h1 of the fixed pattern 521 may be greater than the diameter of the light-emitting diode ED.

The fifth heat dissipation pattern 522_1 may be disposed between the light exit area LA disposed at the outermost position and the non-display area NDA. For example, the fifth heat dissipation pattern 522_1 may be disposed in the first heat dissipation dummy area DMA1.

The fifth heat dissipation pattern 522_1 may be disposed on the first layer 230. The fifth heat dissipation pattern 522_1 may be disposed on the first layer 230 with a second thickness h2. The second thickness h2 may be greater than the first thickness h1.

As the thickness h2 of the fifth heat dissipation pattern 522_1 forming the first dummy pattern DP1 is greater than the thickness h1 of the fixed pattern 521, as will be described below, it is possible to effectively prevent heat generated outside the display area DA from being diffused into the light exit area LA during the cutting process among the processes of fabricating the display device 10.

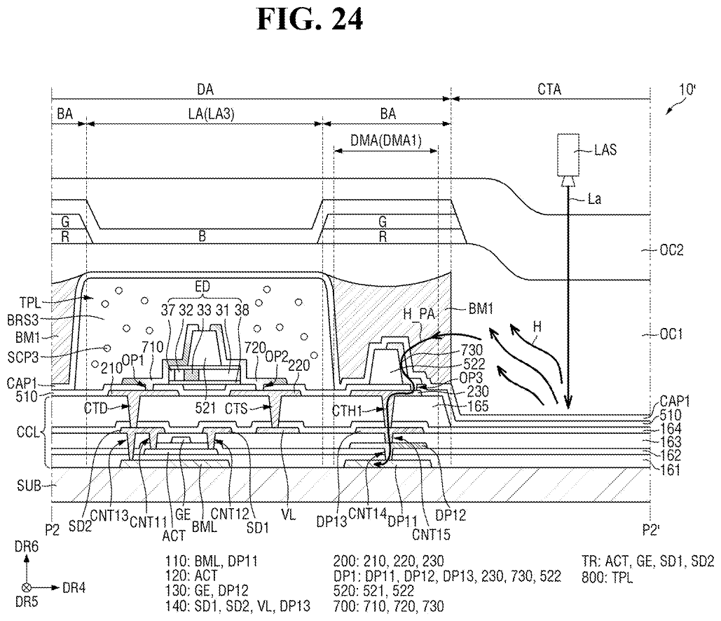

Specifically, during the cutting process among the processes of fabricating the display device 10, a laser beam may be irradiated to a cut area CTA (see FIG. 24) located around the display area DA, as will be described later. In doing so, heat may be generated outside the display area DA by the laser beam. The heat may be diffused from the cut area CTA to the light exit area LA of the display area DA. The fifth heat dissipation pattern 522_1 may be disposed to have the predetermined thickness h2 in the first heat dissipation dummy area DMA1 located between the cut area CTA and the light exit area LA, to form the first dummy pattern DP1. That is to say, is, the fifth heat dissipation pattern 522_1 may serve as a heat shield barrier that prevents diffusion of heat from the cut area CTA to the light exit area LA. Accordingly, as the thickness h2 of the fifth heat dissipation pattern 522_1 increases, the heat shield barrier increases, thereby effectively blocking the diffusion of the heat from the cut area CTA to the light exit area LA.

Accordingly, in the display device 10 according to this embodiment, the fifth heat dissipation pattern 522_1 is thicker than the fixed pattern 521 formed via the same process, so that the fifth heat dissipation pattern 522_1 can more effectively serve as the barrier (heat shield barrier) that blocks heat which otherwise may be diffused from the outside of the display area DA to the light exit area LA. Accordingly, it is possible to reduce damage to the wavelength control layer 800 (the transparent pattern TPL in the drawing) disposed in the light exit area by the heat generated in the cutting process.

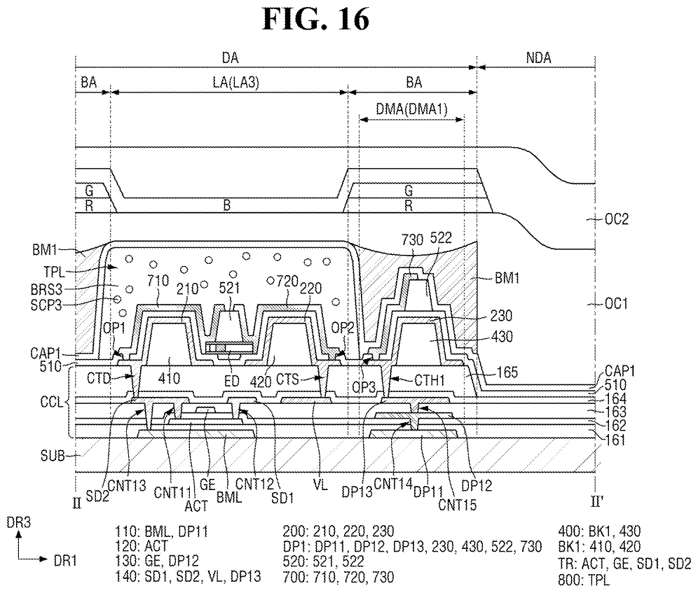

FIG. 16 is a cross-sectional view showing yet another example, taken along line II-II′ of the tiled display of FIG. 6.

A display device 10 according to the embodiment of FIG. 16 is different from the display device according to the embodiment of FIG. 13 in that a light-emitting element layer further includes a third insulating layer 400, and a first dummy pattern DP1 further includes the seventh layer 430.

Specifically, the light-emitting element layer may further include a third insulating layer 400 disposed on the via-layer 165. The third insulating layer 400 may be disposed directly on the upper surface of the via-layer 165, and the third conductive layer 200 may be disposed on the third insulating layer 400.

The third insulating layer 400 may be disposed in the display area DA. The third insulating layer 400 may include a first bank BK1 and a seventh layer 430 of the first dummy pattern DP1. According to an embodiment of the disclosure, the third insulating layer 400 according to the invention may include, but is not limited to, an organic insulating material such as polyimide (PI).

The first bank BK1 may be disposed in the light exit area LA. The first bank BK1 may be disposed in the light exit area LA to provide the space where the light-emitting diode ED is disposed and may also work as reflective partition walls that change the traveling direction of light emitted from the light-emitting diode ED toward the display side.

The first bank BK1 may include a plurality of sub-banks spaced apart from each other. For example, the first bank BK1 may include a first sub-bank 410 and a second sub-bank 420 spaced apart from each other. A plurality of light-emitting diodes ED may be disposed in the space between the first sub-bank 410 and the second sub-bank 420.

At least a part of each of the first and second sub-banks 410 and 420 may protrude from the upper surface of the via-layer 165 upward (e.g., toward one side indicated by the third direction DR3). Each of the first and second sub-banks 410 and 420 may include inclined side surfaces. Since the first and second sub-banks 410 and 420 include the inclined side surfaces, the first and second sub-banks 410 and 420 can direct toward the upper side (e.g., display side) the light, which is emitted from the light-emitting diode ED and travels toward the side surfaces of the first bank BK1. Although the side surfaces of the first and second sub-banks 410 and 420 are linearly inclined in the drawings, the disclosure is not limited thereto. For example, the side surfaces (or the outer surfaces) of the first and second sub-banks 410 and 420 may have a curved semicircle or semi-ellipse shape.

The first sub-bank 410 may be disposed to overlap the first electrode 210 in the third direction DR3 in the light exit area LA. The first sub-bank 410 may overlap the first contact electrode 710 in the third direction DR3.

The second sub-bank 420 may be disposed to overlap the second electrode 220 in the third direction DR3 in the light exit area LA. The second sub-bank 420 may overlap the second contact electrode 720 in the third direction DR3.

The seventh layer 430 of the first dummy pattern DP1 may be spaced apart from the first bank BK1. The seventh layer 430 of the first dummy pattern DP1 may be disposed in the first heat dissipation dummy area DMA1. The seventh layer 430 of the first dummy pattern DP1 may form a part of the first dummy pattern DP1 in the first heat dissipation dummy area DMA1.

The seventh layer 430 of the first dummy pattern DP1 may be made of or include the same material as the first and second sub-banks 410 and 420 of the first bank BK1. The seventh layer 430 of the first dummy pattern DP1 may be disposed in the same layer as the first and second sub-banks 410 and 420 of the first bank BK1. In addition, the seventh layer 430 of the first dummy pattern DP1 may be substantially identical to the shapes of the first and second sub-banks 410 and 420 of the first bank BK1. The seventh layer 430 of the first dummy pattern DP1 and the first and second sub-banks 410 and 420 of the first bank BK1 may be formed simultaneously via a single process. The shape of the seventh layer 430 of the first dummy pattern DP1 is identical to the shape of the first and second sub-banks 410 and 420, and the seventh layer 430 of the first dummy pattern DP1 and the first and second sub-banks 410 and 420 are simultaneously formed via a single process, the seventh layer 430 forming the first dummy pattern DP1 can be formed without any additional mask process or design. As a result, the efficiency of process of fabricating the display device 10 can be effectively improved.

The third conductive layer 200 may be disposed on the third insulating layer 400. Specifically, the first electrode 210 and the second electrode 220 may be disposed on the first bank BK1, and the first layer 230 of the first dummy pattern DP1 may be disposed on the seventh layer 430 of the first dummy pattern DP1.

The first electrode 210 may be disposed on the first sub-bank 410. The first electrode 210 may be disposed to cover the upper surface and inclined side surfaces of the first sub-bank 410. The second electrode 220 may be disposed on the second sub-bank 420. The second electrode 220 may be disposed to cover the upper surface and inclined side surfaces of the second sub-bank 420. The first layer 230 of the first dummy pattern DP1 may be disposed on the seventh layer 430 of the first dummy pattern DP1. The first layer 230 of the first dummy pattern DP1 may be disposed to cover the upper surface and the inclined side surfaces of the seventh layer 430 of the first dummy pattern DP1.

The light-emitting diodes ED may be disposed between the first sub-bank 410 and the second sub-bank 420.

As described above, the first insulating layer 520 may include a fixed pattern 521 disposed in the light exit area LA and a sixth layer 522 of the first dummy pattern DP1 disposed in the first heat dissipation dummy area DMA1.

The fixed pattern 521 may be disposed on the light-emitting diode ED. The fixed pattern 521 may be disposed between the first sub-bank 410 and the second sub-bank 420 in cross-section. The fixed pattern 521 may not overlap the first bank BK1 in the light exit area LA in a plan view.

The sixth layer 522 of the first dummy pattern DP1 may be disposed on the first layer 230 of the first dummy pattern DP1 and the seventh layer 430 of the first dummy pattern DP1. The sixth layer 522 of the first dummy pattern DP1 may overlap the seventh layer 430 of the first dummy pattern DP1 in the first heat dissipation dummy area DMA1 in a plan view.

That is to say, a part of the third insulating layer 400 disposed in the light exit area LA (e.g., the first bank BK1) may not overlap with the first insulating layer 520 disposed in the light exit area LA (specifically, the fixed pattern 521, while a part of the third insulating layer 400 disposed in the first heat dissipation dummy area DMA1 (e.g., the seventh layer 430) may overlap with the first insulating layer 520 disposed in the first heat dissipation dummy area DMA1 (specifically, the sixth layer 522 of the first dummy pattern DP1) in a plan view.

The first and second sub-banks 410 and 420 of the first bank BK1 may overlap the wavelength control layer 800 in a plan view. The wavelength control layer 800 may be disposed on and cover the first and second sub-banks 410 and 420 of the first bank BK1. As shown in the drawings, the first and second sub-banks 410 and 420 disposed in the third light exit area LA3 may be covered by the transparent pattern TPL. The first and second sub-banks 410 and 420 of the first bank BK1 may not overlap the first light-blocking member BM1 disposed in the blocking area BA in a plan view.

The seventh layer 430 of the first dummy pattern DP1 may overlap the first light-blocking member BM1 disposed in the blocking area BA in a plan view. The first light-blocking member BM1 may be disposed on and cover the seventh layer 430 of the first dummy pattern DP1.

According to this embodiment, the first dummy pattern DP1 may include the third layer DP11, the fourth layer DP12, the fifth layer DP13, the first layer 230, the sixth layer 522, the second layer 730 and the seventh layer 430. That is to say, the first dummy pattern DP1 may further include the seventh layer 430 of the first dummy pattern DP1 that has the same shape and is made of or include the same material as the first bank BK1 disposed in the light exit area LA. As the first dummy pattern DP1 further includes the seventh layer 430 of the first dummy pattern DP1 protruding upward from the via-layer 165, and the first and second layers 230 and 730 of the first dummy pattern DP1 and the sixth layer 522 of the first dummy pattern DP1 are disposed on the seventh layer 430 of the first dummy pattern DP1, the height of the first dummy pattern DP1 may be increased by the thickness of the seventh layer 430 of the first dummy pattern DP1. Accordingly, the height of the first dummy pattern DP1 is increased by the seventh layer 430 of the first dummy pattern DP1, so that first dummy pattern DP1 can more effectively serve as the barrier (heat shield barrier) that blocks heat which otherwise may be diffused from the outside of the display area DA to the light exit area LA. Accordingly, it is possible to reduce damage to the wavelength control layer 800 (the transparent pattern TPL in the drawing) disposed in the light exit area by the heat generated in the cutting process.

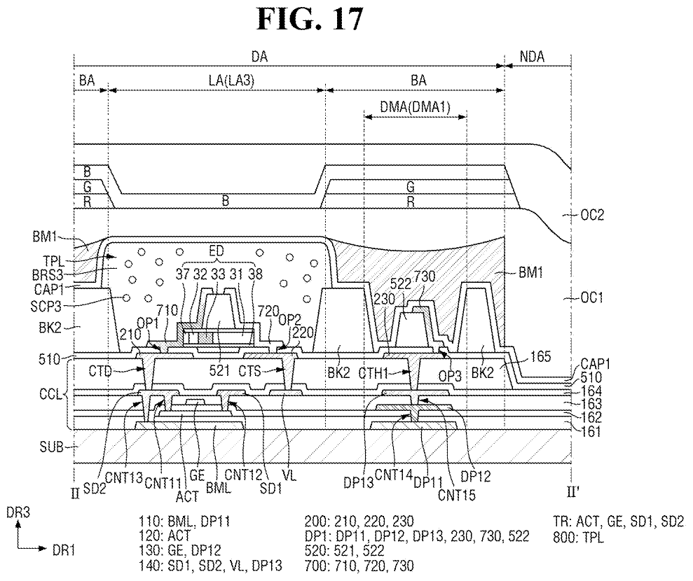

FIG. 17 is a cross-sectional view showing still another example, taken along line II-II′ of the tiled display of FIG. 6.

A display device 10 according to the embodiment of FIG. 17 is different from the display device according to the embodiment of FIG. 13 in that a light-emitting element layer further includes a second bank BK2.

Specifically, the light-emitting element layer may further include the second bank BK2 disposed on the second insulating layer 510. The second bank BK2 may be disposed in the display area DA. The second bank BK2 may be disposed between the plurality of sub-pixels SPXn to distinguish them from one another. The second bank BK2 can prevent an ink containing the light-emitting diodes ED from overflowing into adjacent pixels or sub-pixels PX during an inkjet printing process for aligning the light-emitting diodes ED among the process of fabricating the display device 10.

The second bank BK2 may not be disposed in the first heat dissipation dummy area DMA1 in the blocking area BA. That is to say, the second bank BK2 may include an opening exposing the second insulating layer 510 disposed in the light exit area LA and the first heat dissipation dummy area DMA1. A plurality of patterns forming the pixel and/or a plurality of patterns forming the first dummy pattern DP1 may be disposed on the second insulating layer 510 exposed by the second bank BK2.

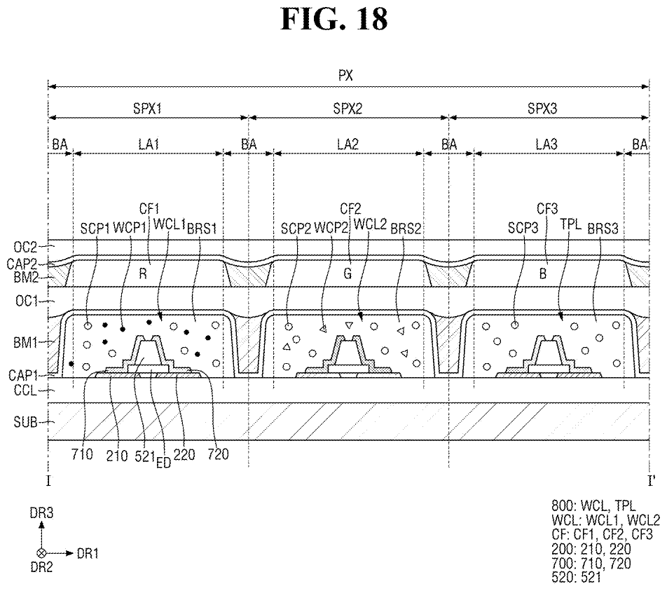

FIG. 18 is a cross-sectional view showing another example, taken along line I-I′ of the tiled display of FIG. 6.

A display device 10 according to the embodiment of FIG. 18 is different from the display device according to the embodiment of FIG. 9 in that the former further includes a second light-blocking member BM2, and the second light-blocking member BM2 is disposed in a blocking area BA in which no color filter layer CF is disposed.

Specifically, the color filter layer CF may be disposed in the light exit area LA and may not be disposed in the blocking area BA. Since the color filter layer CF is disposed in the light exit area LA and not in the blocking area BA, the color filter layer CF may expose the first planarization layer OC1 disposed in the blocking area BA.

The first color filter CF1 may be disposed in the first light exit area LA1, the second color filter CF2 may be disposed in the second light exit area LA2, and the third color filter CF3 may be disposed in the third light exit area LA3.

The second light-blocking member BM2 may be disposed on the first planarization layer OC1 exposed by the color filter layer CF. The second light-blocking member BM2 may be disposed in the blocking area BA of the display area DA along the boundary of the sub-pixel SPXn on the first planarization layer OC1. The second light-blocking member BM2 may overlap the first light-blocking member BM1 in the thickness direction of the display device 10 (e.g., the third direction DR3).

The second light-blocking member BM2 may not only block leakage of light but also suppress reflection of external light. The second light-blocking member BM2 may be arranged in a lattice shape surrounding the first to third light exit areas LA1, LA2 and LA3 when viewed from the top (i.e., in a plan view).

The second light-blocking member BM2 may include an organic material. According to an embodiment of the disclosure, the second light-blocking member BM2 may include a light-absorbing material that absorbs light in the visible wavelength range. The second light-blocking member BM2 may include a light-absorbing material and may be disposed along the boundaries of the sub-pixels SPX: SPX1, SPX2 and SPX3. Accordingly, the second light-blocking member BM2 may define the light exit areas LA: LA1, LA2 and LA3. In other words, the second light-blocking member BM2 may be a subsidiary pixel-defining layer defining the light exit area LA and the blocking area BA of each of the sub-pixels SPXn.

The second capping layer CAP2 may be disposed on the color filter layer CF and the second light-blocking member BM2. The second capping layer CAP2 may be disposed on the color filter layer CF and the second light-blocking member BM2 to cover them. The second capping layer CAP2 may serve to protect the color filter layer CF.

The protection layer OC2 may be disposed on the second capping layer CAP2. For example, the protection layer OC2 may include at least one inorganic film to prevent permeation of oxygen or moisture. In addition, the protection layer OC2 may include at least one organic film to protect the display device 10 from foreign substances such as dust.

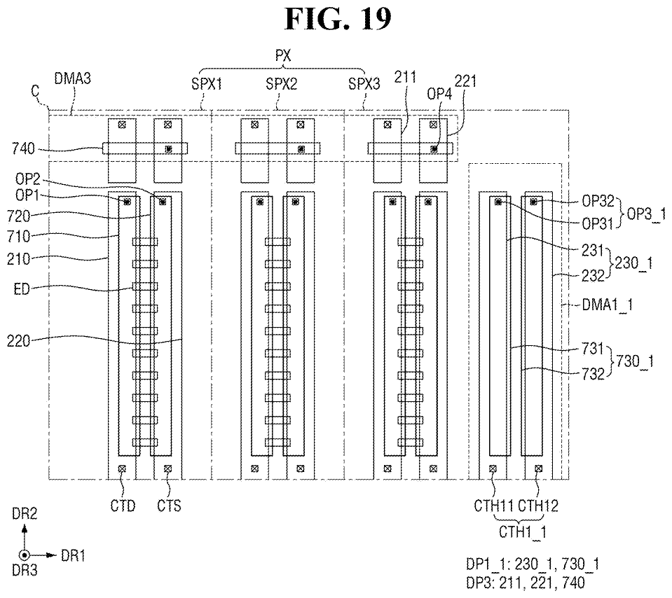

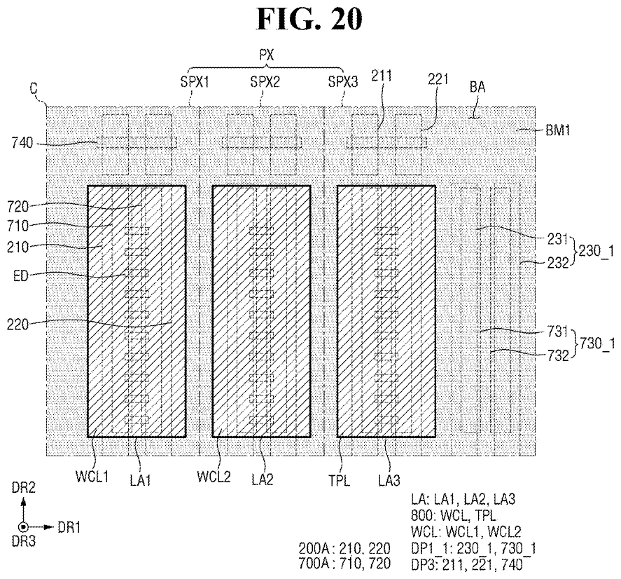

FIG. 19 is an enlarged plan view showing another example of a layout of area C of FIG. 6. FIG. 20 is a plan view showing a wavelength control layer and a first light-blocking member disposed in one pixel shown in FIG. 19.

A display device 10 according to the embodiment of FIGS. 19 and 20 is different from the display device according to the embodiment of FIGS. 10 and 11 in that a pixel pattern disposed in the light exit area LA of each of the sub-pixels SPXn is substantially identical to a first dummy pattern DP1_1 disposed in a first heat dissipation dummy area DMA1_1.

Specifically, a first layer 230_1 of the first dummy pattern DP1_1 disposed in the first heat dissipation dummy area DMA1_1 may have substantially the same pattern with the first electrode 210 and the second electrode 220 disposed in the light exit area LA to form the pixel pattern. The first layer 230_1 may be in contact with at least one of a plurality of conductive layers or a metal layer of the above-described circuit element layer CCL through a first dummy electrode contact hole CTH1_1.

The first layer 230_1 of the first dummy pattern DP1_1 may include a first pattern 231 and a second pattern 232 spaced apart from each other. Each of the first pattern 231 and the second pattern 232 may have a shape extended in the second direction DR2 in the first heat dissipation dummy area DMA1_1. The first pattern 231 and the second pattern 232 may be spaced apart from each other in the first direction DR1.

The first pattern 231 and the second pattern 232 may have substantially the same pattern as the first electrode 210 and the second electrode 220 disposed in the light exit area LA, respectively. The first pattern 231 may be associated with the first electrode 210, and the second pattern 232 may be associated with the second electrode 220.

The first pattern 231 may be in contact with at least one of a plurality of conductive layers or a metal layer of the circuit element layer CCL through a first sub-dummy electrode contact hole CTH11. The second pattern 232 may be in contact with at least one of a plurality of conductive layers of the circuit element layer CCL through a second sub-dummy electrode contact hole CTH12.

The second layer 730_1 of the first dummy pattern DP1_1 may have substantially the same pattern as the first contact electrode 710 and the second contact electrode 720 that are disposed in the light exit area LA and form the pixel pattern. The second layer 730_1 of the first dummy pattern DP1_1 may be in contact with the first layer 230_1 through a third contact opening OP3_1.

The second layer 730_1 of the first dummy pattern DP1_1 may include a third pattern 731 and a fourth pattern 732 spaced apart from each other. The third pattern 731 and the fourth pattern 732 may have a shape extended in the second direction DR2 in the first heat dissipation dummy area DMA1_1. The third pattern 731 and the fourth pattern 732 may be spaced apart from each other in the first direction DR1.

The third pattern 731 and the fourth pattern 732 may have substantially the same pattern as the first contact electrode 710 and the second contact electrode 720 disposed in the light exit area LA, respectively. The third pattern 731 may be associated with the first contact electrode 710, and the fourth pattern 732 may be associated with the second contact electrode 720.

The third pattern 731 may be in contact with the first pattern 231 through a first subsidiary contact opening OP31, and the fourth pattern 732 may be in contact with the second pattern 232 through a second subsidiary contact opening OP32.

Since the light-emitting diodes ED are not disposed in the blocking area BA, the light-emitting diodes ED may not be disposed between the first pattern 231 and the second pattern 232.

The first electrode 210, the second electrode 220, the first layer 230_1 of the first dummy pattern DP1_1, and the first layers 211 and 221 of the third dummy pattern DP3_1 may be simultaneously formed via a single mask process. In addition, the first contact electrode 710, the second contact electrode 720, the second layer 730_1 of the first dummy pattern DP1_1, and the second layer 740 of the third dummy pattern DP3_1 may be simultaneously formed via a single mask process.

According to this embodiment, the first electrode 210 and the second electrode 220 serving as the pixel pattern of each sub-pixel and the first layer 230_1 of the first dummy pattern DP1_1 have the same pattern, and thus no additional design for forming the first dummy pattern DP1_1 is desirable. In addition, since the first contact electrode 710 and the second contact electrode 720 serving as the pixel pattern of each sub-pixel and the second layer 730_1 of the first dummy pattern DP1_1 have the same pattern, no additional design for forming the first dummy pattern DP1_1 is desirable.

In addition, since there are more parts forming the first dummy pattern DP1_1 disposed in the first heat dissipation dummy area DMA1 than those of the display device 10 shown in FIGS. 10 and 11, the area for the heat dissipation paths can be increased. As a result, the heat dissipation area is increased, so that the dissipation efficiency of the heat generated during the cutting process among the processes of fabricating the display device 10 can be effectively improved.

The first light-blocking member BM1 may cover the first pattern 231 and the second pattern 232 forming the first layer 230_1 of the first dummy pattern DP1_1, and the third pattern 731 and the fourth pattern 732 forming the second layer 730_1 of the first dummy pattern DP1_1.

Hereinafter, a cutting process among the processes of fabricating the display device 10 will be described.

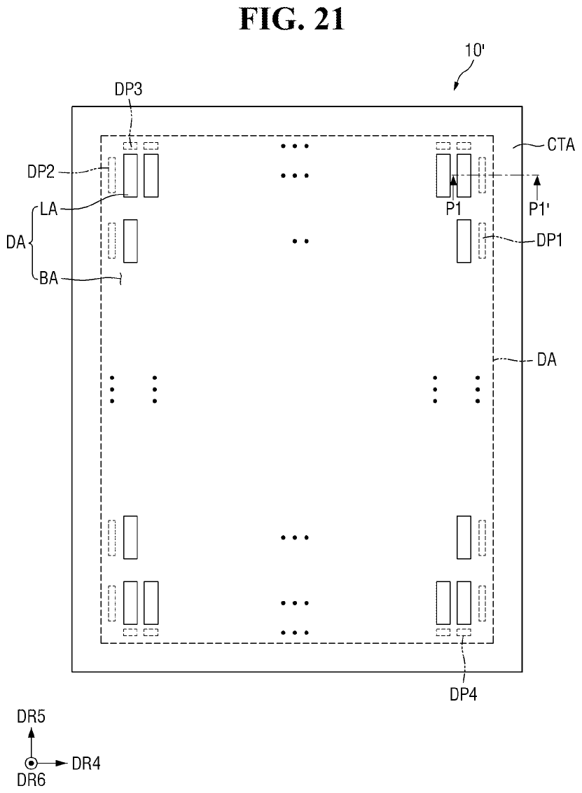

FIGS. 21 to 25 are plan views and cross-sectional views for illustrating a cutting process during a process of fabricating a display device.

In the drawings for illustrating the process of fabricating a display device, a fourth direction DR4, a fifth direction DR5 and a sixth direction DR6 are defined. The fourth direction DR4 and the fifth direction DR5 may be perpendicular to each other in one plane. The sixth direction DR6 may be perpendicular to the plane defined by the fourth and fifth directions DR4 and DR5. The sixth direction DR6 is perpendicular to each of the fourth direction DR4 and the fifth direction DR5. Hereinafter, the sixth direction DR6 refers to the thickness direction of a display mother substrate 10′ (or display side).

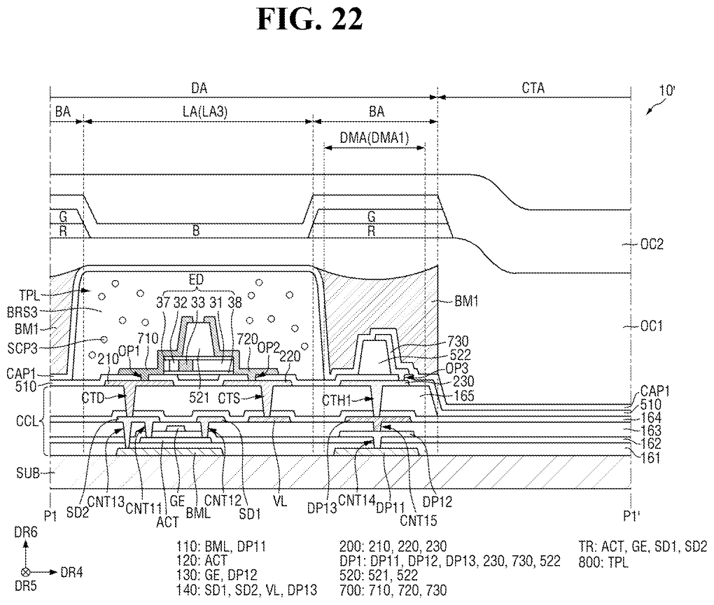

FIG. 21 is a plan view showing an example of the display mother substrate 10′. FIG. 22 is a cross-sectional view showing an example, taken along line P1-P1′ of FIG. 21.

Initially, referring to FIGS. 21 and 22, the display mother substrate 10′ is prepared.

The display mother substrate 10′ may include a display area DA and a cut area CTA.

The display area DA of the display mother substrate 10′ may have the same structure as the display area DA of the display device 10 described above. Accordingly, the display area DA of the display mother substrate 10′ may include a plurality of light exit areas LA and a blocking area BA surrounding the light exit areas LA. The display mother substrate 10′ may include a plurality of dummy patterns DP1, DP2, DP3 and DP4 disposed between the light exit areas LA disposed at the outermost positions of the display area DA and the non-display area NDA.

The cut area CTA may be disposed to surround the display area DA. In the cut area CTA, a process of cutting the outermost parts of the display mother substrate 10′ may be carried out, as will be described below. The cut area CTA may have a structure substantially similar to that of the non-display area NDA of the display device 10 described above, but may have a larger width than the non-display area NDA. The plurality of conductive layers 130 and 140 or the bottom metal layer 110 of the circuit element layer CCL may not be disposed in the cut area CTA. In addition, the plurality of conductive layers 200 and 700 of the light-emitting element layer may not be disposed in the cut area CTA.

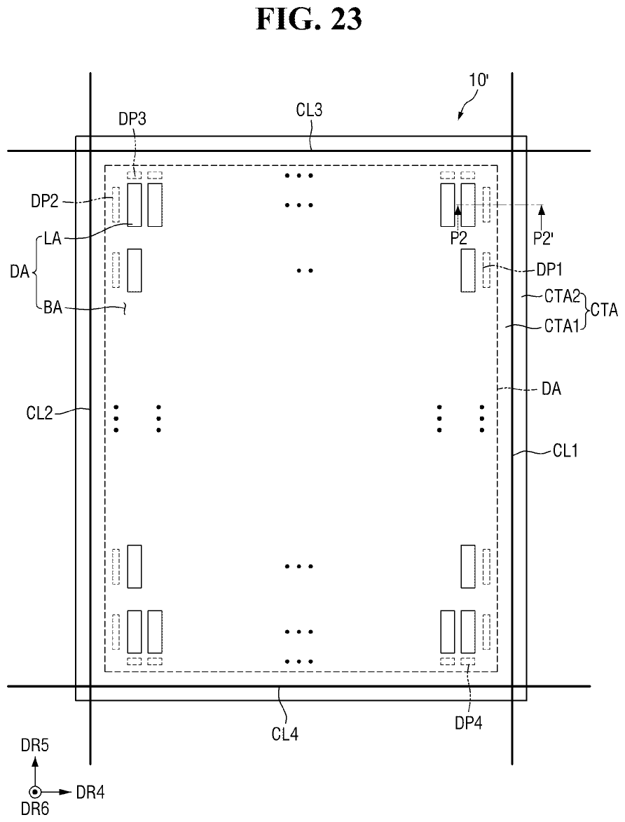

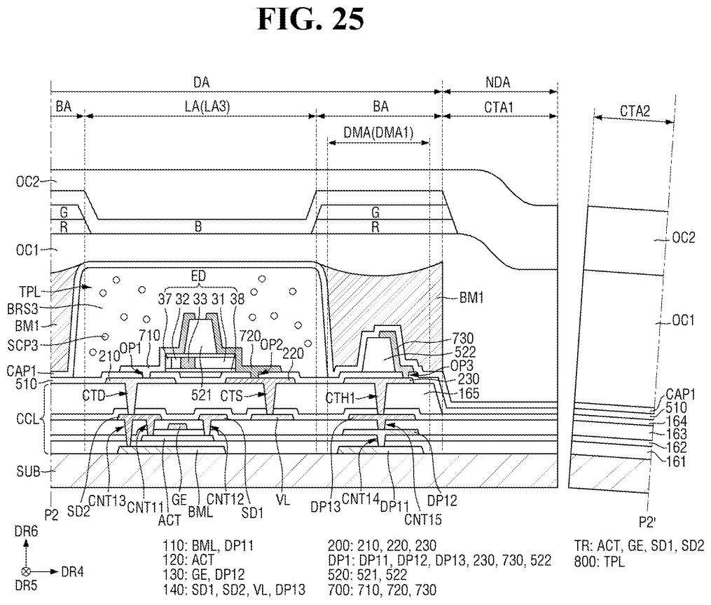

FIG. 23 is a plan view showing cutting lines CL1, CL2, CL3 and CL4 on the display mother substrate 10′ of FIG. 21. FIGS. 24 and 25 are cross-sectional views showing a process of cutting the display mother substrate 10′.

Subsequently, referring to FIGS. 23 to 25, a part of the display mother substrate 10′ is cut using a laser source LAS.

Specifically, the display device 10 may be fabricated by cutting the display mother substrate 10′ along the first and second cutting lines CL1 and CL2 extended in the fifth direction DR5 and the third and fourth cutting lines CL3 and CL4 extended in the fourth direction DR4. The first to fourth cutting lines CL1, CL2, CL3 and CL4 may be located in the cut area CTA.

By using the laser source LAS, a laser beam La is irradiated onto the cut area CTA of the display mother substrate 10′ to cut the part of the display mother substrate 10′. The substrate SUB of the display mother substrate 10′ may include a glass substrate. When the substrate SUB includes a glass substrate, the glass substrate may be cut by irradiating a high-energy laser beam La. Therefore, heat H may be generated by the laser beam La irradiated to cut the substrate SUB. The heat H may be diffused from the cut area CTA toward the light exit areas LA of the display mother substrate 10′.

As mentioned earlier, in order to prevent a user from recognizing the boundary area SA of the tiled display TD or to reduce the bezel of the display device 10, it is desirable to reduce the width of the non-display area NDA of the display device 10. In order to reduce the width of the non-display area NDA, a laser beam La may be irradiated to portions of the cut area CTA of the display mother substrate 10′ that are adjacent to the display area DA during the process of cutting the display mother substrate 10′. In doing so, heat H generated by the laser beam Layer may be easily transferred (or diffused) to the light exit areas LA. According to this embodiment, by arranging the plurality of dummy patterns DP1, DP2, DP3 and DP4 in the heat dissipation dummy area DMA located between the cut area CTA and the light exit areas LA of the display area DA, heat dissipation paths for the heat H can be provided.

Specifically, the heat H generated by the laser beam La irradiated to the cut area CTA may be diffused from the cut area CTA to the display area DA. The heat H may be transferred to the second layer 730 of the first dummy pattern DP1. The heat H transferred to the second layer 730 of the first dummy pattern DP1 may be transferred from the first layer 230 of the first dummy pattern DP1 to the first layer 230 of the first dummy pattern DP1 in contact with it through the third contact opening OP3. The heat H transferred to the first layer 230 of the first dummy pattern DP1 may be transferred from the first layer 230 of the first dummy pattern DP1 to the fifth layer DP13 of the first dummy pattern DP1 in contact with it through the first dummy electrode contact hole CTH1. In addition, the heat H transferred to the fifth layer DP13 of the first dummy pattern DP1 may be transferred from the fifth layer DP13 of the first dummy pattern DP1 to the fourth layer DP12 of the first dummy pattern DP1 in contact with it through the contact hole CNT15. In addition, the heat H transferred to the fourth layer DP12 of the first dummy pattern DP1 may be transferred from the fourth layer DP12 of the first dummy pattern DP1 to the third layer DP11 of the first dummy pattern DP1 in contact with it through the contact hole CNT14.

That is to say, since the first dummy pattern DP1 has the structure in which the layers including a metal material are in direct contact with each other through at least one contact hole, the heat H generated by the laser source LAS may have heat dissipation paths through the plurality of layers of the first dummy pattern DP1. For example, there may be a path through which the heat H transferred to the first dummy pattern DP1 may be transferred from the second layer 730 of the first dummy pattern DP1 at the top to the third layer DP11 of the first dummy pattern DP1 at the bottom. In this manner, it is possible to prevent damage to a plurality of elements disposed in the light exit area LA, e.g., the light-emitting diodes ED, the wavelength control layer 800, etc. by the heat H.

The cut area CTA may be divided into a first cut area CTA1 disposed on the inner side of the first to fourth cutting lines CL1, CL2, CL3 and CL4, and a second cut area CTA2 on the outer side thereof. The first cut area CTA1 disposed on the inner side of the first to fourth cutting lines CL1, CL2, CL3 and CL4 may correspond to the non-display area NDA of the display device 10.

Although the display mother substrate 10′ includes one display area DA, and the cutting lines CL1, CL2, CL3 and CL4 are located along the edges of the display mother substrate 10′ in the drawings, the disclosure is not limited thereto. For example, the display mother substrate may include a plurality of unit substrates corresponding to the display devices 10, respectively, and during the process of cutting the display mother substrate, cutting areas between the unit substrates are cut to fabricate the plurality of display devices 10.

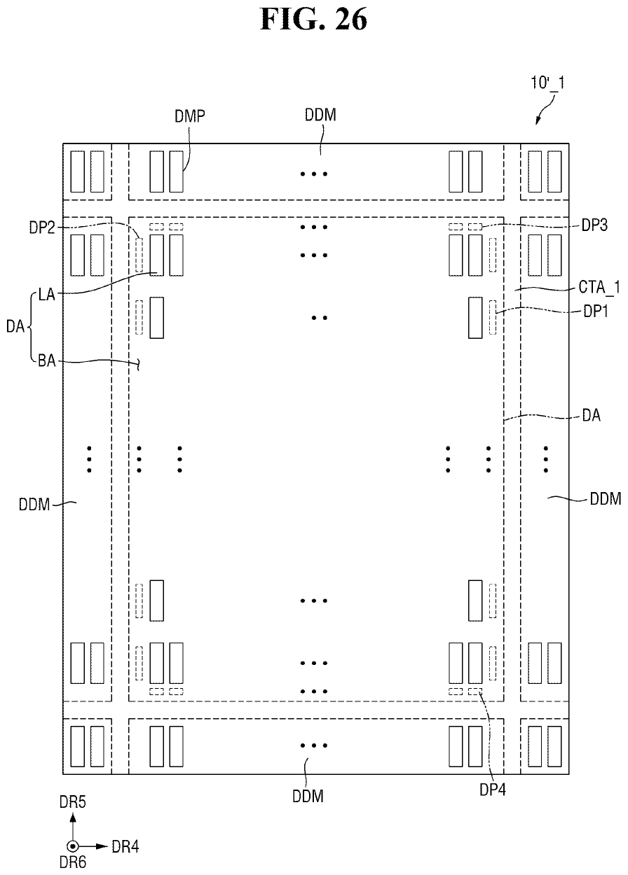

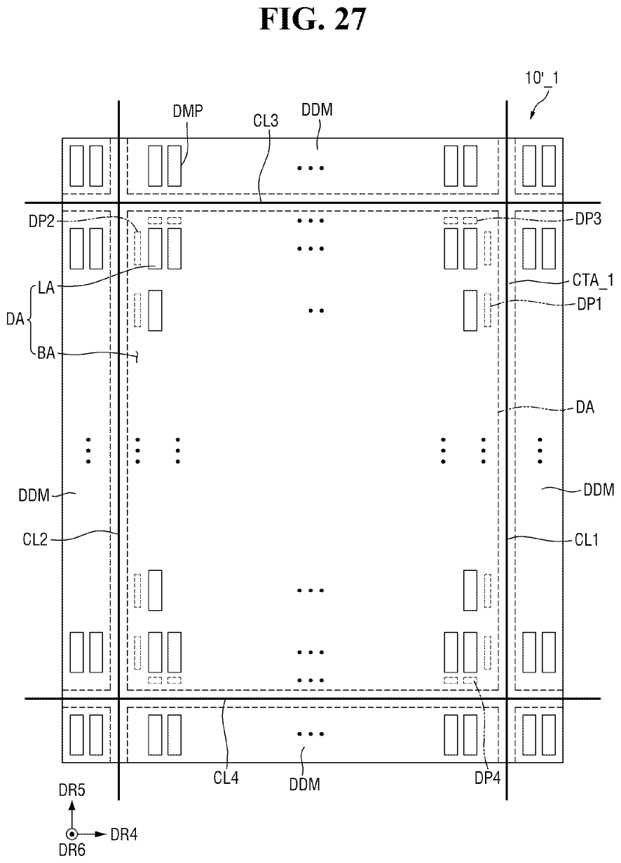

FIGS. 26 and 27 are cross-sectional views showing another example of a display mother substrate.

FIG. 26 is a plan view showing another example of a display mother substrate 10′_1. FIG. 27 is a plan view showing cutting lines CL1, CL2, CL3 and CL4 on the display mother substrate 10′ of FIG. 26.

A display mother substrate 10′ 1 according to the embodiment of FIGS. 26 and 27 is different from the display mother substrate 10′ according to the embodiment of FIGS. 21 and 23 in that the former further includes dummy pixel areas DDM at the edges.

Specifically, the display mother substrate 10′_1 may further include the dummy pixel area DDM at the edges thereof. In the dummy pixel areas DDM, a plurality of dummy pixels DMP may be disposed. The structure of each of the plurality of dummy pixels DMP may be substantially identical to that of the pixels PX disposed in the display area DA. By forming the plurality of dummy pixels DMP at the edges of the display mother substrate 10′_1, it is possible to reduce deviations in the arrangement density of the plurality of light-emitting diodes ED included in the pixels PX positioned in the display area DA. Specifically, the dummy pixels DMP are further disposed on the outer side of the display area DA of the display mother substrate 10′, and during an inkjet printing process of aligning a plurality of light-emitting diodes ED, an ink is ejected in advance to the dummy pixels DMP to align a plurality of light-emitting diodes ED, so that the number of light-emitting diodes ED disposed in the display area DA can be uniform.

When the display mother substrate 10′ further includes the dummy pixel areas DDM in which the dummy pixels DMP are disposed at the edges, by cutting a cut area CTA_1 located between the dummy pixel areas DDM and the display area DA to separate the dummy pixel areas DDM, the display device 10 can be fabricated.

In concluding the detailed description, those skilled in the art will appreciate that many variations and modifications can be made to the preferred embodiments without substantially departing from the principles of the invention. Therefore, the disclosed preferred embodiments of the invention are used in a generic and descriptive sense only and not for purposes of limitation.

What is claimed is:

1. A display device comprising:
a substrate having a display area and a non-display area which are defined thereon;
a circuit element layer disposed on the substrate and comprising a conductive layer;
an electrode layer disposed on the circuit element layer and comprising first and second electrodes spaced apart from each other;
a light-emitting element disposed between the first electrode and the second electrode; and
a dummy pattern disposed in a heat dissipation dummy area located at an edge of the display area,
wherein the dummy pattern comprises a first layer and a second layer, the first layer is made of or includes a same material as the conductive layer of the circuit element layer, and the second layer is disposed above the first layer and in contact with at least a part of the first layer.

2. The display device of claim 1, wherein the second layer is made of or includes a same material as the electrode layer.

3. The display device of claim 2, wherein the first layer is disposed in a same layer as the conductive layer, and wherein the second layer is disposed in a same layer as the electrode layer.

4. The display device of claim 1, wherein at least one of the first layer and the second layer comprises a metal material.

5. The display device of claim 1, wherein the first electrode and the second electrode are extended in a first direction and are spaced apart from each other in a second direction intersecting the first direction, and wherein the second layer is spaced apart from the electrode layer in the second direction.

6. The display device of claim 5, wherein the second layer has a same shape as the first electrode in a plan view.

7. The display device of claim 5, wherein the second layer comprises a first pattern and a second pattern spaced apart from each other on the first layer, wherein the first pattern has a same shape as the first electrode in a plan view, and wherein the second pattern has a same shape as the second electrode in the plan view.

8. The display device of claim 1, wherein the first electrode and the second electrode are extended in a first direction and are spaced apart from each other in a second direction intersecting the first direction, and wherein the second layer is spaced apart from the electrode layer in the first direction.

9. The display device of claim 8, wherein the second layer comprises a first pattern and a second pattern spaced apart from each other on the first layer, wherein the first pattern is disposed on a virtual extension line of the first electrode in a plan view, and wherein the second pattern is disposed on a virtual extension line of the second electrode in the plan view.

10. The display device of claim 1, further comprising:
a first contact electrode in contact with the first electrode and a first end of the light-emitting element; and
a second contact electrode in contact with the second electrode and a second end of the light-emitting element,
wherein the second layer is made of or includes a same material as one of the electrode layer, the first contact electrode, and the second contact electrode.

11. The display device of claim 1, further comprising:
a first contact electrode in contact with the first electrode and a first end of the light-emitting element; and
a second contact electrode in contact with the second electrode and a second end of the light-emitting element,
wherein the dummy pattern further comprises a third layer disposed on the second layer,
wherein the second layer is made of or includes a same material as the electrode layer, and
wherein the third layer is made of a same material or includes as one of the first contact electrode and the second contact electrode.

12. The display device of claim 1, wherein the circuit element layer further comprises a via-layer disposed on the conductive layer and the first layer,
wherein the electrode layer and the second layer are disposed on the via-layer,
wherein the first electrode is in contact with the conductive layer through a first contact hole penetrating the via-layer, and
wherein the second layer is in contact with the first layer through a second contact hole penetrating the via-layer.

13. The display device of claim 12, wherein the display area comprises a light exit area and a blocking area surrounding the light exit area,
wherein the light exit area is located on an inner side of the heat dissipation dummy area in the display area,
wherein the dummy pattern is disposed in the blocking area located between the light exit area and the non-display area, and
wherein the light-emitting element is disposed between the first electrode and the second electrode in the light exit area.

14. The display device of claim 13, further comprising:
a wavelength control layer disposed over the light-emitting element in the light exit area; and
a light-blocking member disposed on the via-layer in the blocking area,
wherein the light-blocking member covers the dummy pattern.

15. The display device of claim 13, further comprising:
a bank disposed between the via-layer and the electrode layer in the light exit area,
wherein the dummy pattern further comprises a third layer disposed between the via-layer and the second layer in the heat dissipation dummy area, and
wherein the third layer is made of or includes a same material as the bank.

16. The display device of claim 1, further comprising:
a fixed pattern disposed on the light-emitting element to expose opposite ends of the light-emitting element,
wherein the dummy pattern further comprises a third layer disposed on the second layer, and
wherein the fixed pattern and the third layer are made of or include a same material.

17. A display device comprising:
a substrate having a display area and a non-display area which are defined thereon, wherein the display area comprises a light exit area and a heat dissipation dummy area;
a semiconductor layer disposed on the substrate and located in the display area;
a gate insulator disposed on the semiconductor layer;
a first conductive layer disposed on the gate insulator and comprising a gate electrode located in the display area;
an interlayer dielectric film disposed on the first conductive layer;
a second conductive layer disposed on the interlayer dielectric film, and comprising a source electrode and a drain electrode located in the display area, and a first heat dissipation dummy pattern located in the heat dissipation dummy area;
a via-layer disposed on the second conductive layer and located in the display area;
a third conductive layer disposed on the via-layer, and comprising first and second electrodes at least partially located in the light exit area, and a second heat dissipation pattern located in the heat dissipation dummy area; and
a plurality of light-emitting elements disposed in the light exit area,
wherein the heat dissipation dummy area is located between the light exit area and the non-display area,
wherein the first electrode and the second electrode are spaced apart from each other,
wherein the plurality of light-emitting elements is disposed between the first electrode and the second electrode,
wherein the first electrode is electrically connected to the source electrode through a first contact hole penetrating the via-layer, and
wherein the second heat dissipation pattern is in direct contact with the first heat dissipation pattern through a second contact hole penetrating the via-layer.

18. A tiled display comprising a plurality of display devices, wherein each of the display device comprises
a substrate having a display area and a non-display area which are defined thereon;
a circuit element layer disposed on the substrate and comprising a conductive layer;
an electrode layer disposed on the circuit element layer and comprising first and second electrodes spaced apart from each other;
a light-emitting element disposed between the first electrode and the second electrode; and
a dummy pattern disposed in a heat dissipation dummy area located at an edge of the display area,
wherein the dummy pattern comprises a first layer and a second layer, the first layer is made of or includes a same material as the conductive layer of the circuit element layer, and the second layer is disposed above the first layer and in contact with at least a part of the first layer.

19. The tiled display of claim 18, wherein the second layer is made of or includes a same material as the electrode layer.

20. The tiled display of claim 19, wherein the first layer is disposed in a same layer as the conductive layer, and wherein the second layer is disposed in a same layer as the electrode layer.
